(19) United States
(12) Patent Application Publication
(10) Pub. No.: US 2025/0107162 A1
(43) Pub. Date: Mar. 27, 2025

(54) TRANSISTOR STRUCTURES FOR MINIMIZING SUBTHRESHOLD HUMP EFFECT

(71) Applicant: Cirrus Logic International Semiconductor Ltd., Edinburgh (GB)

(72) Inventors: Kuen-Ting SHIU, Round Rock, TX (US); Suman BANERJEE, Austin, TX (US); Claude ORTOLLAND, Austin, TX (US); Marc L. TARABBIA, Austin, TX (US); Caitlin BRANDON, Austin, TX (US); Jin TANG, Cupertino, CA (US)

(73) Assignee: Cirrus Logic International Semiconductor Ltd., Edinburgh (GB)

(21) Appl. No.: 18/585,438

(22) Filed: Feb. 23, 2024

Related U.S. Application Data
(60) Provisional application No. 63/585,250, filed on Sep. 26, 2023.

(51) Int. Cl. H01L 29/06; H01L 21/762; H01L 27/02; H01L 29/08

(52) U.S. Cl. CPC H10D 62/102; H01L 21/76224; H10D 62/151; H10D 89/10

(57) ABSTRACT

A semiconductor structure may include a substrate having a surface, an isolation structure formed on the surface, an active region formed on the surface adjacent to the isolation structure, a gate extended over the isolation structure and the active region, and a source region formed within the active region. The source region may include a first subregion formed adjacent to a first portion of the gate and the isolation structure, the first subregion having a first doping and a second subregion formed adjacent to a second portion of the gate, wherein the second subregion has a second doping different from the first doping.

### RELATED APPLICATION

The present disclosure claims priority to U.S. Provisional Patent Application Ser. No. 63/585,250, filed Sep. 26, 2023, which is incorporated by reference herein in its entirety.

### FIELD OF DISCLOSURE

The present disclosure relates in general to semiconductor fabrication, and more particularly, to fabrication of and use of certain structural features in a field-effect transistor (FET), such as a metal-oxide-semiconductor field-effect transistor (MOSFET) to minimize the subthreshold hump effect present in MOSFETs.

### BACKGROUND

Semiconductor device fabrication is a process used to create integrated circuits that are present in many electrical and electronic devices. It is a multiple-step sequence of photolithographic, mechanical, and chemical processing steps during which electronic circuits are gradually created on a wafer made of semiconducting material. For example, during semiconductor device fabrication, numerous discrete circuit components, including transistors, resistors, capacitors, inductors, and diodes may be formed on a single semiconductor die.

A transistor is a semiconductor device with many uses. Generally speaking, a transistor is a semiconductor device used to amplify or switch electronic signals and electrical power. It is composed of semiconductor material usually with at least three terminals for connection to an external circuit. Typically, a voltage or current applied to one pair of the transistor's terminals controls the current through another pair of terminals. One common type of transistor is a metal-oxide-semiconductor field-effect transistor (MOSFET). A typical MOSFET comprises an insulated gate, whose voltage determines the conductivity of the device as seen between two other non-gate terminals of the device, known as a drain terminal and a source terminal. The MOSFET's ability to change conductivity with the amount of applied voltage allows it to be used for amplifying or switching electronic signals.

One particular problem of MOSFETs may be referred to as the subthreshold hump effect. The effect arises from shallow-trench isolation (STI) processes used in manufacturing of an isolation structure of a MOSFET, in which a divot may appear along an edge of the active region of the MOSFET. The presence of such divot may cause non-uniformities along polysilicon and the STI edge and leads to parasitic transistors within the MOSFET having a lower threshold voltage than the core transistor of the MOSFET. Both the parasitic transistors and the core transistor may contribute to the total drain current of the MOSFET. Due to the smaller threshold voltage of the parasitic transistors, the resulting drain current versus gate-to-source voltage curve of the MOSFET may exhibit a “hump” (i.e., the “subthreshold hump”) at smaller gate-to-source voltages within the subthreshold region of the MOSFET. The subthreshold hump may lead to higher leakage currents, local mismatches, and undesirable noise behavior within an analog circuit. Accordingly, it may be desirable to reduce or eliminate this subthreshold hump effect.

### SUMMARY

In accordance with the teachings of the present disclosure, certain disadvantages and problems associated with existing approaches to manufacturing MOSFETs may be reduced or eliminated.

In accordance with embodiments of the present disclosure, a semiconductor structure may include a substrate having a surface, an isolation structure formed on the surface, an active region formed on the surface adjacent to the isolation structure, a gate extended over the isolation structure and the active region, and a source region formed within the active region. The source region may include a first subregion formed adjacent to a first portion of the gate and the isolation structure, the first subregion having a first doping and a second subregion formed adjacent to a second portion of the gate, wherein the second subregion has a second doping different from the first doping.

In accordance with these and other embodiments of the present disclosure, a semiconductor structure may include a substrate having a surface, an isolation structure formed on the surface, an active region formed on the surface adjacent to the isolation structure, a gate extended over the isolation structure and the active region, and a source region formed within the active region. The source region may include a first subregion formed adjacent to the gate and the isolation structure and a second subregion formed adjacent to the gate, wherein the first subregion is surrounded by the isolation structure and the second subregion. The semiconductor structure may also include a silicide layer formed over the second subregion, in contact with the second subregion, and separated from the first subregion.

In accordance with these and other embodiments of the present disclosure, an integrated circuit may include a substrate having a surface, an isolation structure formed on the surface, and a transistor over the substrate. The transistor may comprise an active region formed on the surface adjacent to the isolation structure, a gate extended over the isolation structure and the active region, and a source region formed within the active region. The source region may include a first subregion formed adjacent to a first portion of the gate and the isolation structure, the first subregion having a first doping, and a second subregion formed adjacent to a second portion of the gate, wherein the second subregion has a second doping different from the first doping.

In accordance with these and other embodiments of the present disclosure, an integrated circuit may include a substrate having a surface, an isolation structure formed on the surface, and a transistor over the substrate. The substrate may include an active region formed on the surface adjacent to the isolation structure, a gate extended over the isolation structure and the active region, and a source region formed within the active region. The source region may include a first subregion formed adjacent to the gate and the isolation structure and a second subregion formed adjacent to the gate, wherein the first subregion is surrounded by the isolation structure and the second subregion. The transistor may also include a silicide layer formed over the second subregion, in contact with the second subregion, and separated from the first subregion.

In accordance with these and other embodiments of the present disclosure, a method may include forming an isolation structure formed on a surface of a substrate, forming an active region on the surface adjacent to the isolation structure, extending a gate over the isolation structure and the active region, and forming a source region formed within the active region, the source region comprising a first subregion adjacent to a first portion of the gate and the isolation structure, the first subregion having a first doping and a second subregion adjacent to a second portion of the gate, wherein the second subregion has a second doping different from the first doping.

In accordance with these and other embodiments of the present disclosure, a method may include forming an isolation structure formed on a surface of a substrate, forming an active region on the surface adjacent to the isolation structure, and extending a gate over the isolation structure and the active region. The method may also include forming a source region within the active region, the source region comprising a first subregion adjacent to the gate and the isolation structure, and a second subregion adjacent to the gate, wherein the first subregion is surrounded by the isolation structure and the second subregion. The method may further include forming a silicide layer over the second subregion, in contact with the second subregion, and separated from the first subregion.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a top-down plan view of a conventional transistor structure, as is known in the art;

FIG. 2 illustrates a top-down plan view of an example transistor structure, in accordance with embodiments of the present disclosure;

FIG. 3 illustrates an example equivalent circuit diagram of the transistor structure of FIG. 2, in accordance with embodiments of the present disclosure;

FIG. 4 illustrates a top-down plan view of the transistor structure of FIG. 2, with certain physical dimensions annotated, in accordance with embodiments of the present disclosure;

FIGS. 5A and 5B respectively illustrate a top-down plan view of the transistor structure of FIG. 2 and a cross-sectional side elevation view of the transistor structure of FIG. 2, in accordance with embodiments of the present disclosure;

FIGS. 6A and 6B respectively illustrate a top-down plan view of the MOSFET of FIG. 2 and another cross-sectional side elevation view of the MOSFET of FIG. 2, in accordance with embodiments of the present disclosure;

FIGS. 7A, 7B, and 7C respectively illustrate a top-down plan view of an example transistor structure with selective silicide blocking, a cross-sectional side elevation view of the transistor structure taken along either of Path 1 or Path 3 of FIG. 7A, and a cross-sectional side elevation view of the transistor structure taken along Path 2 of FIG. 7A, in accordance with embodiments of the present disclosure;

FIGS. 8A and 8B respectively illustrate a top-down plan view of the transistor structure of FIG. 2 and a cross-sectional side elevation view of the transistor structure of FIG. 2 during a first step of a fabrication process, in accordance with embodiments of the present disclosure;

FIGS. 9A and 9B respectively illustrate a top-down plan view of the transistor structure of FIG. 2 and a cross-sectional side elevation view of the transistor structure of FIG. 2 during a second step of a fabrication process, in accordance with embodiments of the present disclosure;

FIGS. 10A and 10B respectively illustrate a top-down plan view of the transistor structure of FIG. 2 and a cross-sectional side elevation view of the transistor structure of FIG. 2 during a third step of a fabrication process, in accordance with embodiments of the present disclosure;

FIGS. 11A, 11B, and 11C respectively illustrate a top-down plan view of the transistor structure of FIG. 2, a first cross-sectional side elevation view of the transistor structure of FIG. 2 during a fourth step of a fabrication process and a second cross-sectional side elevation view of the transistor structure of FIG. 2 during the fourth step of the fabrication process, in accordance with embodiments of the present disclosure;

FIGS. 12A and 12B respectively illustrate a top-down plan view of the transistor structure of FIG. 2 and a cross-sectional side elevation view of the transistor structure of FIG. 2 during a fifth step of a fabrication process, in accordance with embodiments of the present disclosure;

FIGS. 13A and 13B respectively illustrate a top-down plan view of the transistor structure of FIG. 7 and a cross-sectional side elevation view of the transistor structure of FIG. 7 during an alternative fifth step of a fabrication process, in accordance with embodiments of the present disclosure;

FIGS. 14A, 14B, and 14C respectively illustrate a top-down plan view of the transistor structure of FIG. 2, a first cross-sectional side elevation view of the transistor structure of FIG. 2 during a sixth step of a fabrication process and a second cross-sectional side elevation view of the transistor structure of FIG. 2 during the sixth step of the fabrication process, in accordance with embodiments of the present disclosure;

FIG. 15 illustrates a top-down plan view of an example transistor structure with an active area which is staggered on either side of a gate of the transistor structure, in accordance with embodiments of the present disclosure;

FIG. 16 illustrates a top-down plan view of an example transistor structure with pad oxides formed under a gate of the transistor structure proximate to parasitic transistors, in accordance with embodiments of the present disclosure;

FIGS. 17A and 17B respectively illustrate a top-down plan view of the transistor structure of FIG. 16 and a cross-sectional side elevation view of the transistor structure of FIG. 16, in accordance with embodiments of the present disclosure;

FIGS. 18A and 18B respectively illustrate a top-down plan view of the transistor structure of FIG. 16 and another cross-sectional side elevation view of the transistor structure of FIG. 16, in accordance with embodiments of the present disclosure;

FIGS. 19A and 19B respectively illustrate a top-down plan view of the transistor structure of FIG. 16 and yet another cross-sectional side elevation view of the transistor structure of FIG. 16, in accordance with embodiments of the present disclosure;

FIG. 20 illustrates a top-down plan view of the transistor structure of FIG. 16, with certain physical dimensions annotated, in accordance with embodiments of the present disclosure;

FIG. 21 illustrates a top-down plan view of an example transistor structure with pad oxides partially formed under a gate of the transistor structure proximate to parasitic transistors, in accordance with embodiments of the present disclosure;

FIG. 22 illustrates a top-down plan view of an example transistor structure with pad oxides partially formed at the edges of the active region of the transistor structure, in accordance with embodiments of the present disclosure;

FIG. 23 illustrates a top-down plan view of an example transistor structure with pad oxides formed entirely under a gate of the transistor structure proximate to parasitic transistors, in accordance with embodiments of the present disclosure;

FIG. 24 illustrates a cross-sectional side elevation of an example transistor structure with pad oxides formed under a gate of the transistor structure proximate to parasitic transistors, and with the source and/or drain of the transistor structure doped with different concentrations, in accordance with embodiments of the present disclosure;

FIGS. 25A and 25B respectively illustrate a top-down plan view of the transistor structure of FIG. 16 and a cross-sectional side elevation view of the transistor structure of FIG. 16 during a first step of a fabrication process, in accordance with embodiments of the present disclosure;

FIGS. 26A and 26B respectively illustrate a top-down plan view of the transistor structure of FIG. 16 and a cross-sectional side elevation view of the transistor structure of FIG. 16 during a second step of the fabrication process, in accordance with embodiments of the present disclosure;

FIGS. 27A, 27B, and 27C respectively illustrate a top-down plan view of the transistor structure of FIG. 16, a first cross-sectional side elevation view of the transistor structure of FIG. 16 during a third step of a fabrication process and a second cross-sectional side elevation view of the transistor structure of FIG. 16 during the third step of the fabrication process, in accordance with embodiments of the present disclosure;

FIG. 28 illustrates a block diagram of an example circuit design system, in accordance with embodiments of the present disclosure;

FIG. 29 illustrates a block diagram of an example synthesis software tool, in accordance with embodiments of the present disclosure; and

FIG. 30 illustrates a flow chart of an example method for synthesizing an integrated circuit design with a transistor structure shown and described herein, in accordance with the present disclosure.

### DETAILED DESCRIPTION

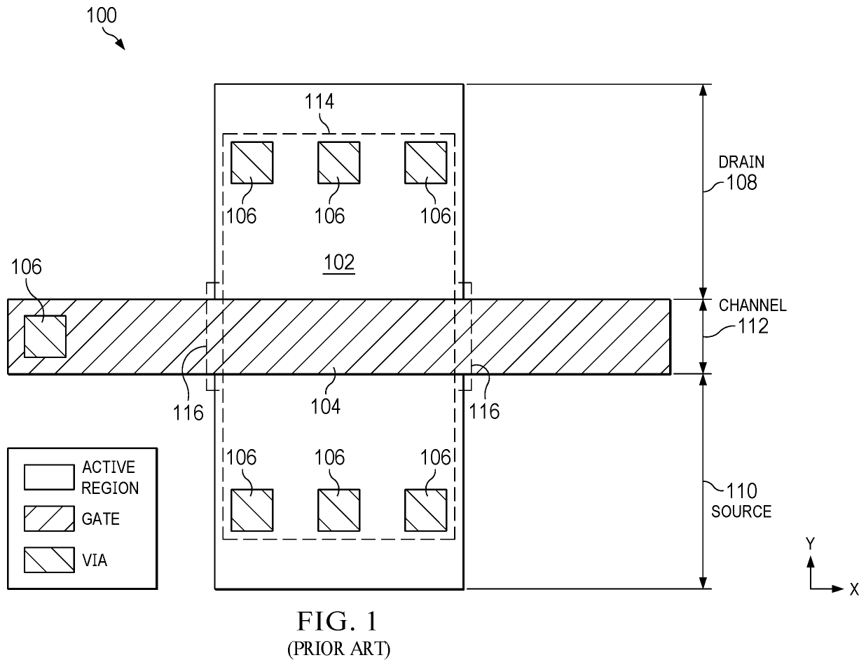

FIG. 1 illustrates a top-down plan view of a conventional FET 100, as is known in the art. As shown in FIG. 1, FET 100 may include an active region 102 formed in a semiconductor substrate (e.g., silicon wafer), with a gate 104 formed over a portion of active region 102, and one or more vias 106 formed upon active region 102 and gate 104, thus splitting active region 102 into a drain region 108, a source region 110, and a channel region 112 that may be configured to transport carriers along the y-direction depicted in FIG. 1. In FET 100, the width of channel region 112 (e.g., in the x-axis depicted in FIG. 1) may be approximately equal to the width of drain region 108 and/or the width of source region 110. FET 100 may be formed using an STI process, thus resulting in, in addition to a core transistor 114, parasitic transistors 116 being present in divots resulting from the STI process, as described in the Background section.

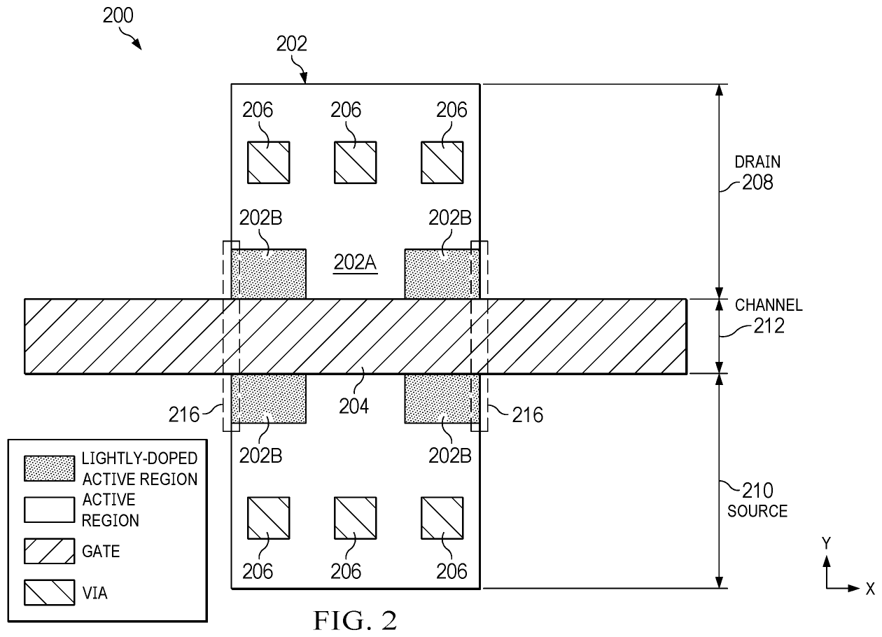

FIG. 2 illustrates a top-down plan view of an example FET 200 with reduced source/drain doping for parasitic transistors, in accordance with embodiments of the present disclosure. As shown in FIG. 2, FET 200 may include an active region 202 formed in a semiconductor substrate (e.g., silicon wafer). FET 200 may further include an isolation structure (not explicitly labeled in FIG. 2) formed by an STI process to surround active region 202. FET 200 may further include a gate 204 formed over active region 202 along the x-direction shown in FIG. 1 (e.g., perpendicular to the channel direction of FET 200), and one or more vias 206 formed upon active region 202 and gate 204, thus splitting active region 202 into a drain region 208, a source region 210, and a channel region 212.

Active region 202 may include a first subregion 202A and one or more second subregions 202B. Second subregions 202B may be at edge portions of active region 202 in the x-direction. In some embodiments, second subregions 202B may be further sandwiched by first subregion 202A in the y-direction (e.g., parallel to the channel direction of FET 200). In some embodiments, an edge of a second subregion 202B may be at one edge of active region 202, where one or more other edges of such second subregion 202B may be adjacent to first subregion 202A. As illustrated in FIG. 2, gate 204 may be horizontally (e.g., along x-direction) extended through first subregion 202A and second subregions 202B to respectively form a core transistor of FET 200 (not explicitly shown in FIG. 2) and parasitic transistors 216.

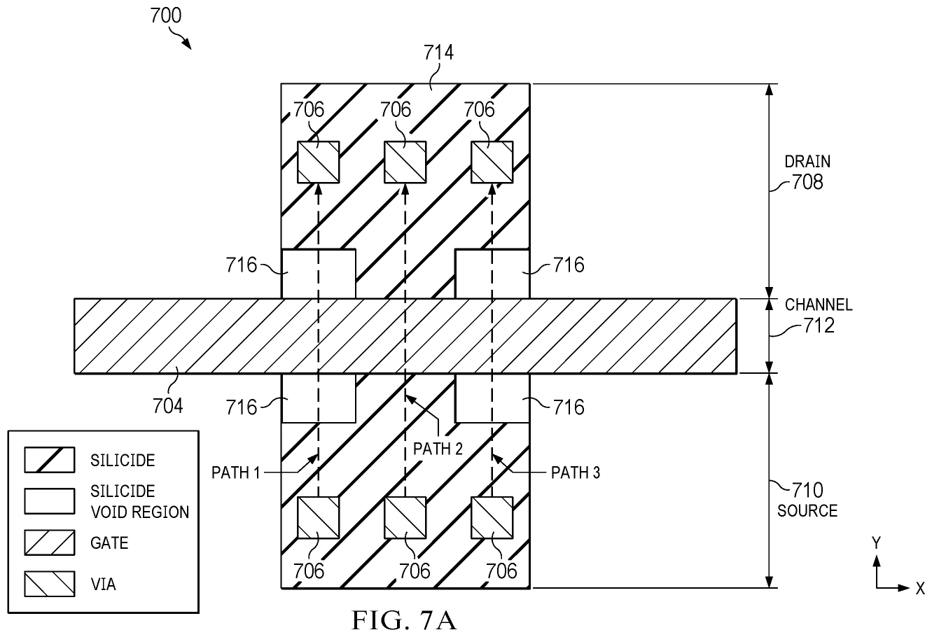

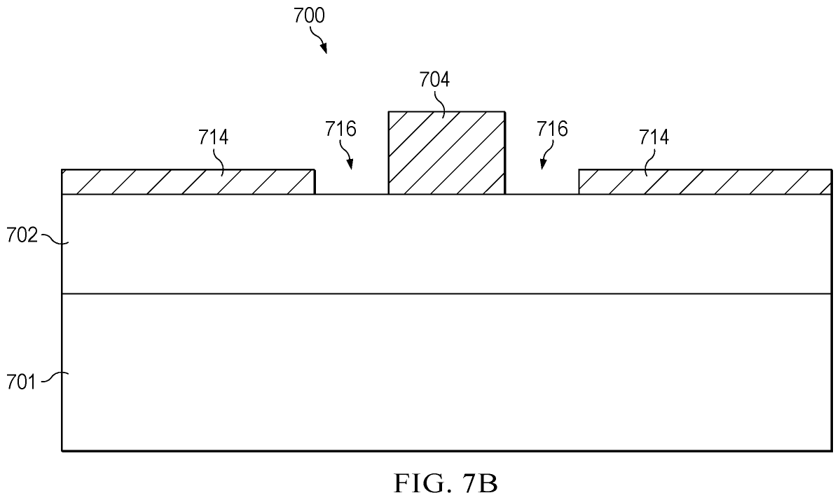

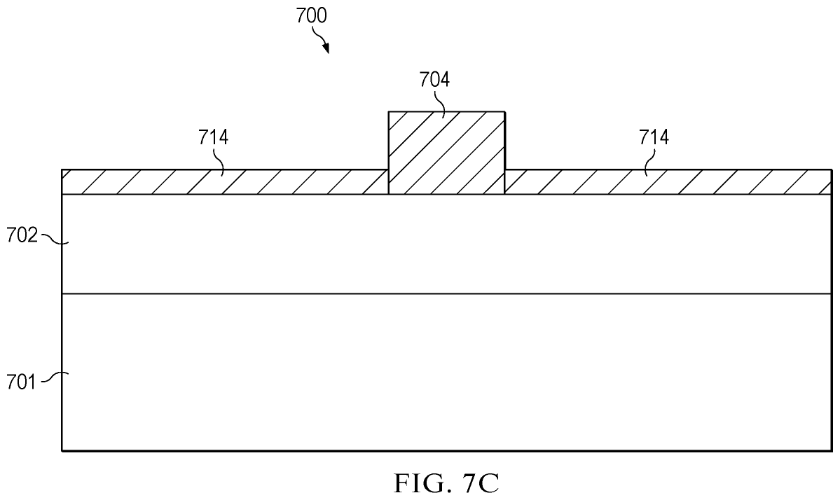

Second subregions 202B may have a greater electrical resistance than first subregion 202A. For example, first subregion 202A may be more heavily doped than second subregions 202B. In some embodiments, first subregion 202A may further include a silicide layer formed at first subregion 202A's top surface, where a top region of second subregions 202B may be separated from the silicide layer (e.g., wherein no silicide is formed in voids 716 as discussed below with respect to FIG. 7).

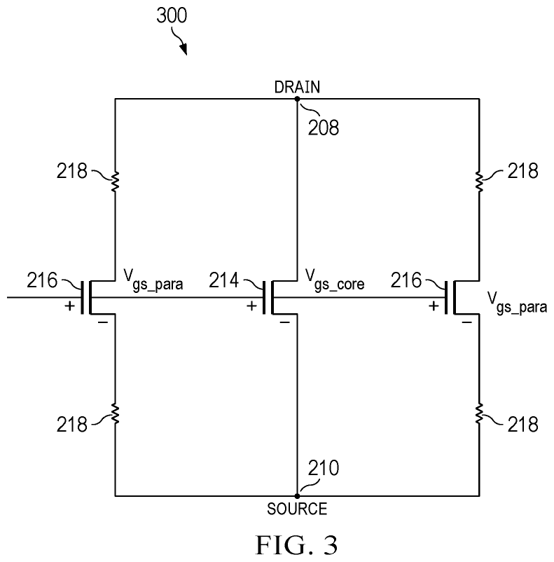

FET 200 may be formed using an STI process, thus resulting in parasitic transistors 216 being present in divots resulting from the STI process. However, as compared to FET 100, due to the high electrical resistance of second subregions 202B, parasitic transistors 216 of FET 200 may have greater resistance as compared to that of parasitic transistors 116 in FET 100. Such additional resistance (as compared to FET 100) between the source region 210/drain region 208 and the channel region 212 of parasitic transistors 216 is shown by the annotation of resistors 218 on FIG. 3.

FIG. 3 illustrates an example equivalent circuit diagram 300 of FET 200, in accordance with embodiments of the present disclosure. As shown in FIG. 3, FET 200 may be represented by a core transistor 214 in parallel with each of two combinations of a resistor 218, parasitic transistor 216, and another resistor 218 in series, thus showing that the paths of parasitic transistors 216 include additional resistance (represented by resistors 218) which may not be present in conventional FET 100. Thus, the gate-source voltages V_{GS_PARA} across parasitic transistors 216 may be smaller than the gate-source voltage V_{GS_CORE} across core transistor 214, meaning the drain current of FET 200 contributed by parasitic transistors 216 may be reduced (e.g., as compared to the drain current of FET 100 contributed by parasitic transistors 116), which may reduce (e.g., as compared to FET 100) or eliminate the subthreshold bump effect in FET 200.

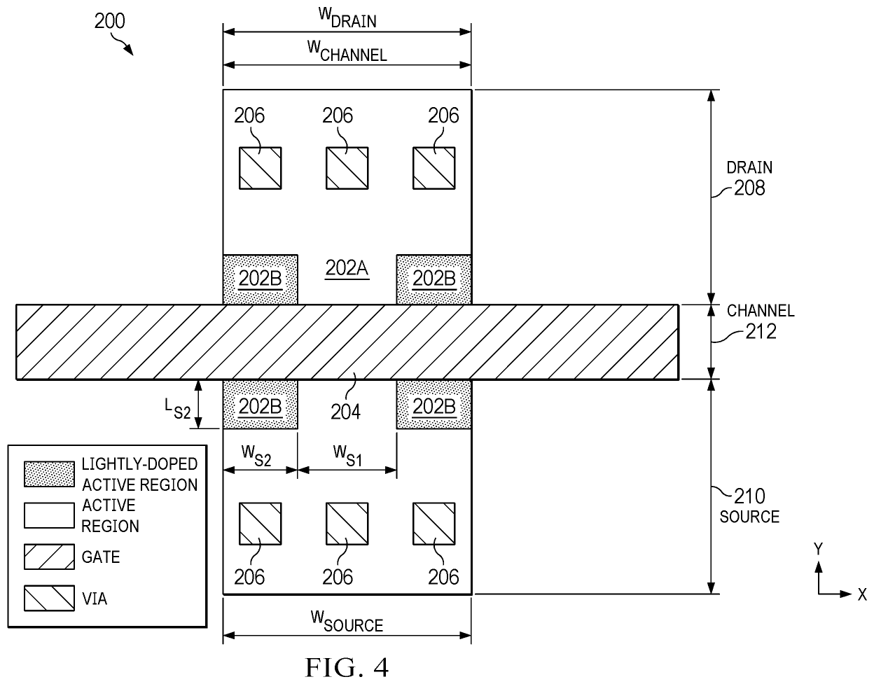

FIG. 4 illustrates a top-down plan view of FET 200, with certain physical dimensions annotated, in accordance with embodiments of the present disclosure. As shown in FIG. 4, a width W_{DRAIN} of drain region 208, a width W_{SOURCE} of source region 210, and a width W_{CHANNEL} of channel region 212, may be approximately the same.

Further, as shown in FIG. 4, in source region 210, first subregion 202A may have a width W_{S1} proximate to channel region 212 and second subregions 202B may each have a width W_{S2}, such that W_{SOURCE}=W_{S1}+2W_{S2}. As previously described above, the doping level of first subregion 202A may be greater than that of second subregions 202B. For example, in some embodiments, second subregions 202B may be undoped (e.g., no intentional doping). As another example, in some embodiments, second subregions 202B may be doped with a dopant having a different polarity than that used to dope first subregion 202A. As a further example, in some embodiments, second subregions 202B may be doped with a semi-insulating dopant, such as a deep-level impurity (e.g., oxygen).

In some instances, based on the level of the doping of second subregions 202B, width W_{S2} may be greater than or equal to approximately 0.05 μm in order to provide sufficient separation of parasitic transistor 216 from core transistor 214 (in FIG. 3) laterally in the x-direction shown in FIG. 4. Further, in some cases, based on the level of the doping of second subregions 202B, it may be required that width W_{S2} is less than or equal to a length L_{S2} of second subregions 202B in a direction perpendicular to the direction of width W_{SOURCE}, in order to provide sufficient layout squares needed to provide sufficient resistance (e.g., represented by resistors 218 of FIG. 3) within the path of parasitic resistors 216. In these and other instances, first subregion 202A must be wide enough

$$( e . g . , \frac{{W}_{s 1}}{{W}_{SOURCE}} \geq 0.9 )$$

to ensure that core transistor 214 is able to provide sufficient source current.

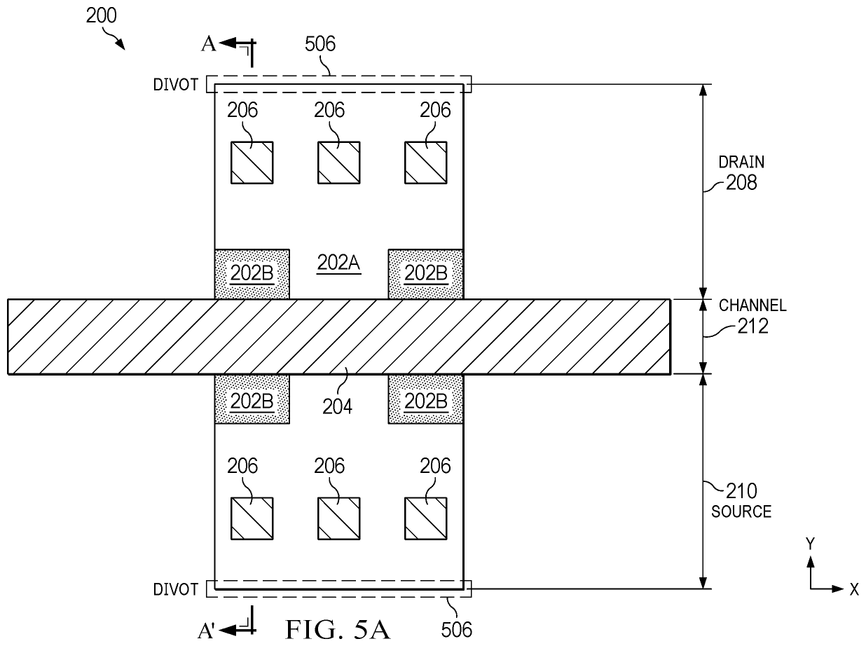

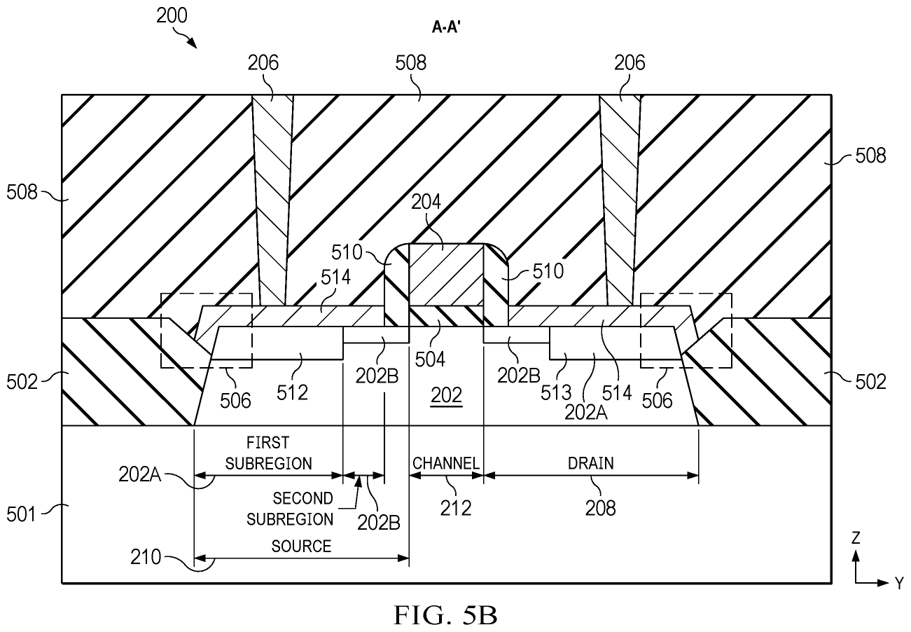

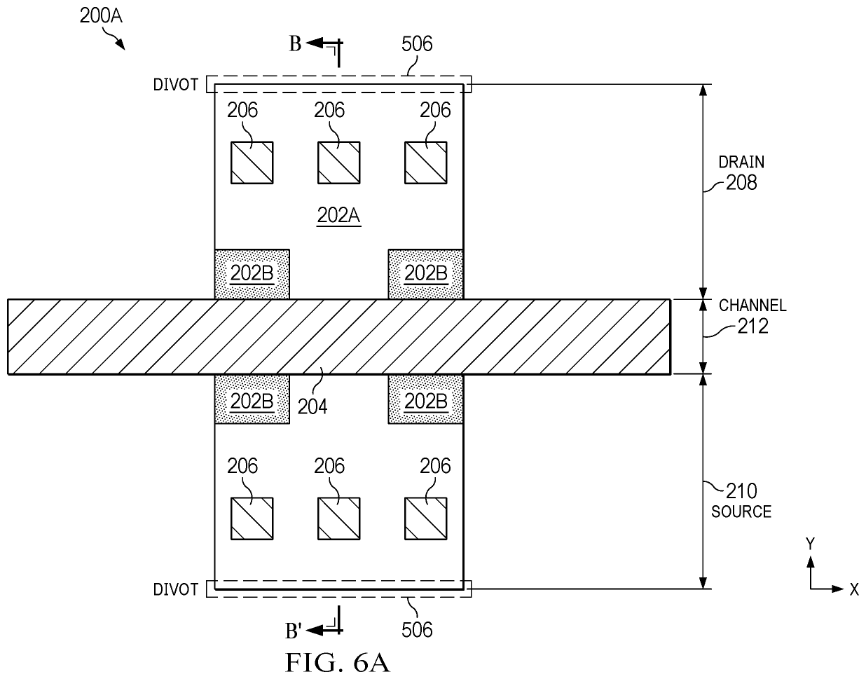

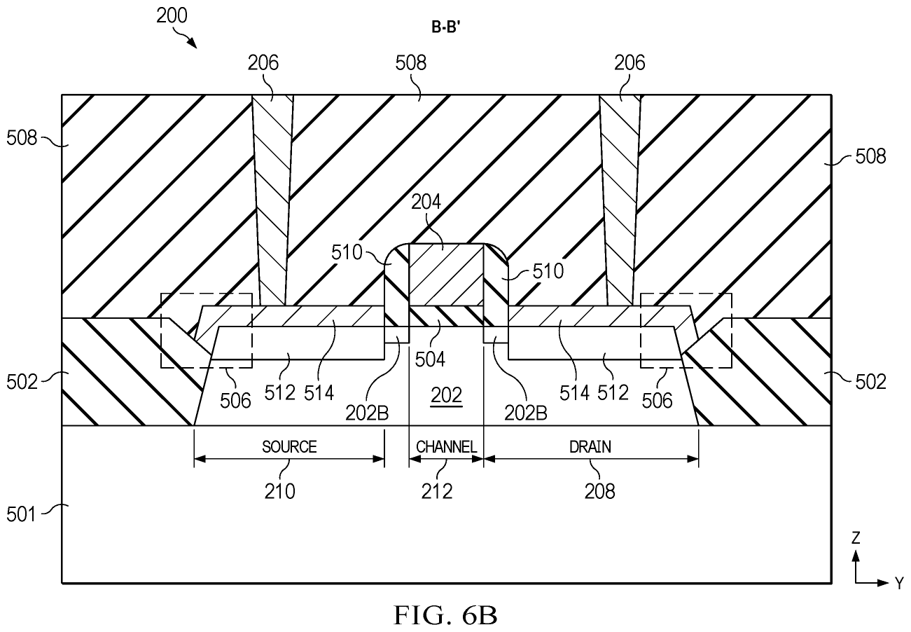

FIG. 5A illustrates a top-down plan view of FET 200 and FIG. 5B illustrates a cross-sectional side elevation view of the FET 200 taken along A-A′ of FIG. 5A, in accordance with embodiments of the present disclosure. FIG. 6A illustrates a top-down plan view of FET 200 and FIG. 6B illustrates a cross-sectional side elevation view of the FET 200 taken along B-B′ of FIG. 6A, in accordance with embodiments of the present disclosure.

Notably, FIGS. 5B and 6B depict STI being made of silicon oxide (SiO) 502 formed on substrate 501 adjacent to channel region 212 of active region 202, which may leave divots 506 along edges of active region 202 in channel region 212. FIGS. 5B and 6B additionally show source doping 512 in source region 210 and drain doping 513 in drain region 208. FIGS. 5B and 6B also depict a gate oxide 504 present between the electrode of gate 204 and channel region 212, to provide dielectric insulation between gate 204 and channel region 212. FIGS. 5B and 6B further depict gate spacers 510 formed adjacent to gate 204, a silicide layer 514 formed over drain region 208 and source region 210, a dielectric layer 508 formed over the features of FET 200, and vias 206 formed within dielectric layer 508 to provide electrical connection to source region 202. As additionally shown in FIGS. 5B and 6B, first subregion 202A may be formed with lightly-doped drain/source doping together with normal drain/source doping, while second subregions 202B may be formed using lightly-doped drain/source doping.

In these and other embodiments, drain region 208 may have its own subregions of similar or identical dimensions as those described above with respect to source region 210 and shown in FIG. 2. In the various views depicted in FIGS. 5A-6B above, some portions of FET 200 may not be shown for purposes of clarity and exposition.

FIG. 7A illustrates a top-down plan view of an example FET 700 with selective silicide blocking, in accordance with embodiments of the present disclosure. FIG. 7B illustrates a cross-sectional side elevation view of the FET 700 taken along either of Path 1 or Path 3 of FIG. 7A, in accordance with embodiments of the present disclosure. FIG. 7C illustrates a cross-sectional side elevation view of the FET 700 taken along Path 2 of FIG. 7A, in accordance with embodiments of the present disclosure. As shown in FIGS. 7A-7C, FET 700 may include an active region 702 formed in a semiconductor substrate 701 (e.g., silicon wafer), with a gate 704 formed over active region 702, and a silicide layer 714 formed over some portions of active region 702 not covered by gate 704, with voids 716 in silicide layer 714 present proximate to gate 704 at the edges of active region 702, thus splitting active region 702 into a drain region 708, a source region 710, and a channel region 712. In some embodiments, silicide layer 714 may be formed over a portion (e.g., such as first subregion 202A as previously discussed) of active region 702, where voids 716 may be formed over another portion (e.g., such as second subregions 202B as previously discussed) of active region 702 to block forming silicide layer 714 over thereon.

FET 700 may be similar in many respects to FET 200, with a noticeable difference that voids 716 of FET 700 may be located at analogous positions to second subregions 202B of FET 200. Voids 716 may likewise lead to paths of parasitic transistors (not shown) near divots (not shown) of FET 700 having greater resistance than a core transistor (not shown) of FET 700, thus potentially minimizing the subthreshold bump effect.

In some embodiments, voids 716 may only be present in source region 710. In other embodiments, voids 716 may only be present in drain region 708. In these and other embodiments, voids 716 may extend throughout the source region 710 and/or the drain region 708 in the y-direction shown in FIG. 7. In these and other embodiments, the same doping may be used throughout drain region 708 and/or source region 710.

Further, in some embodiments, a MOSFET may include the features of FET 200 having reduced source/drain doping for parasitic transistors and the selective silicide blocking features of FET 700, in order to provide for greater resistance in the paths of parasitic transistors than the core transistor for such MOSFET.

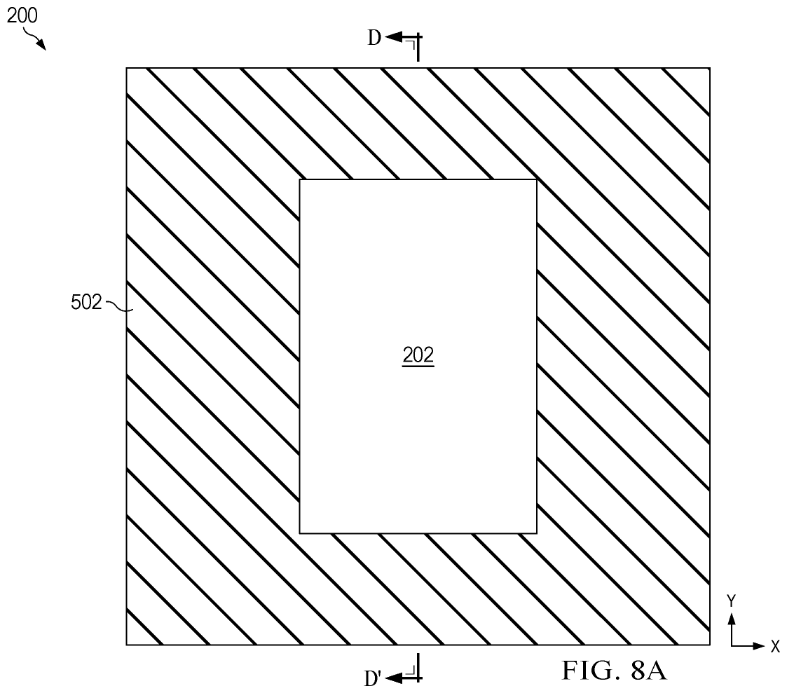

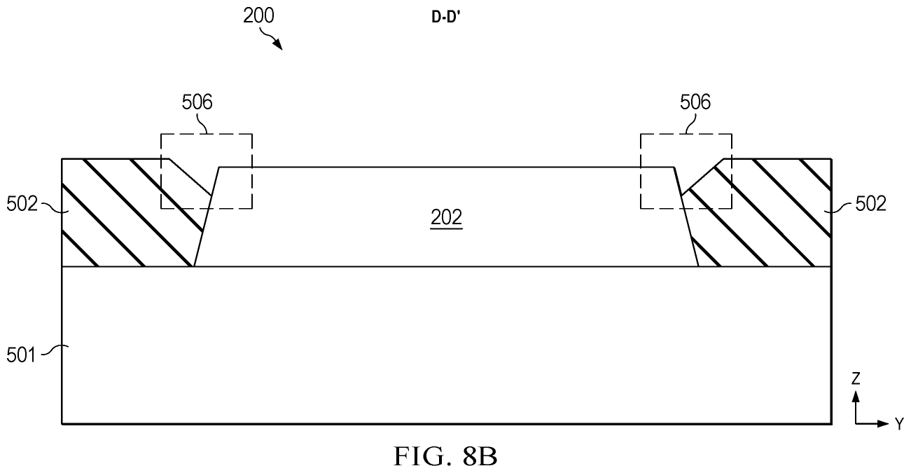

FIGS. 8A and 8B respectively illustrate a top-down plan view of the MOSFET of FET 200 and a cross-sectional side elevation view of FET 200 taken along D-D′ of FIG. 8A during a first step of a fabrication process, in accordance with embodiments of the present disclosure. As shown in FIGS. 8A and 8B, during such first step, active region 202 may be formed on substrate 501, and STI may be performed to form a trench in SiO 502, leaving divots 506 between active region 202 and SiO 502. A step similar to this first step may also be used to fabricate FET 700.

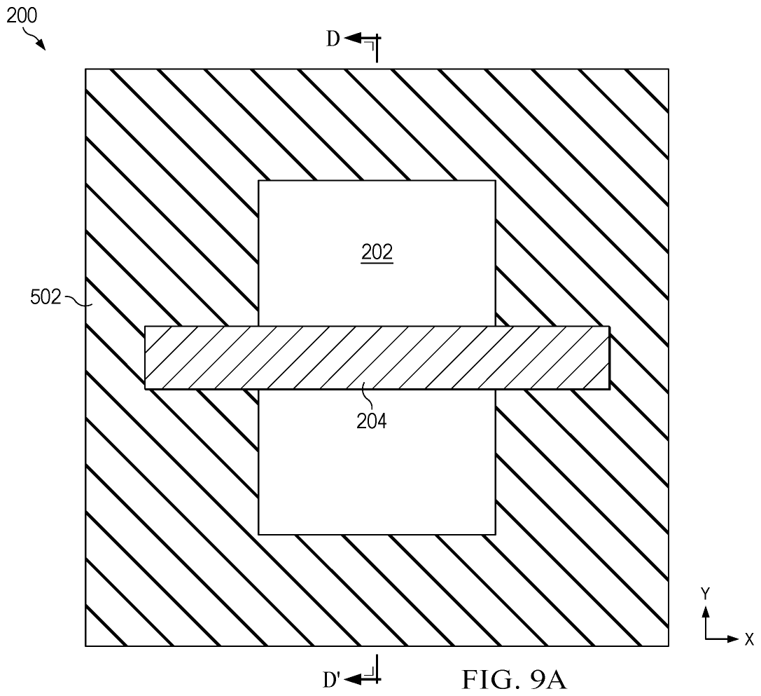

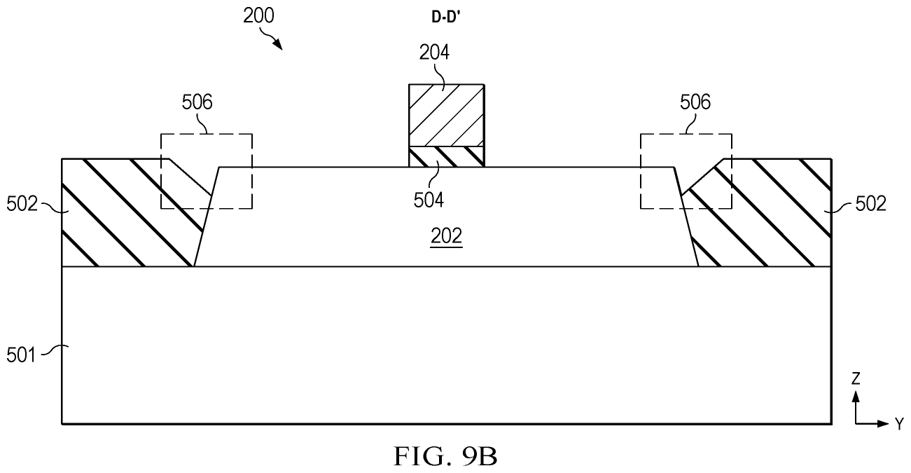

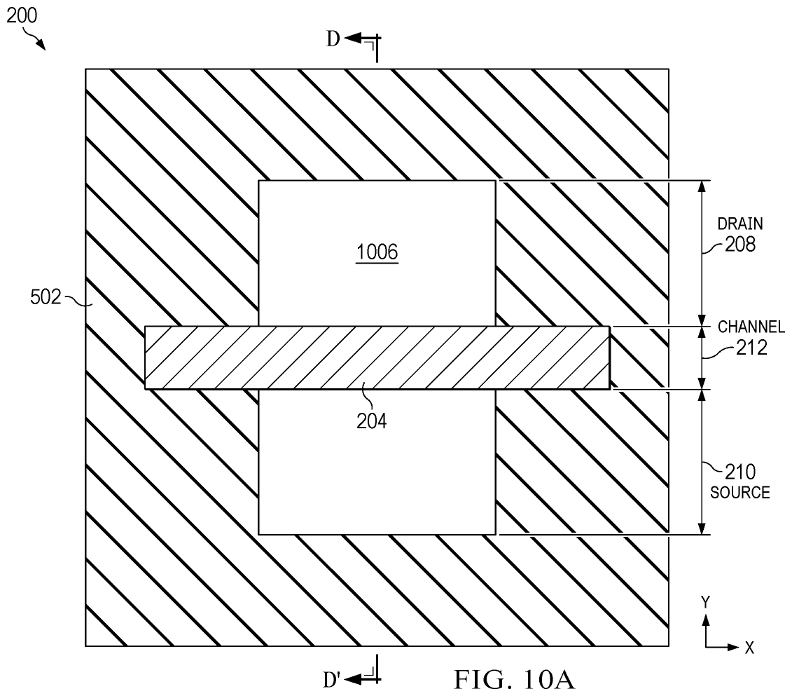

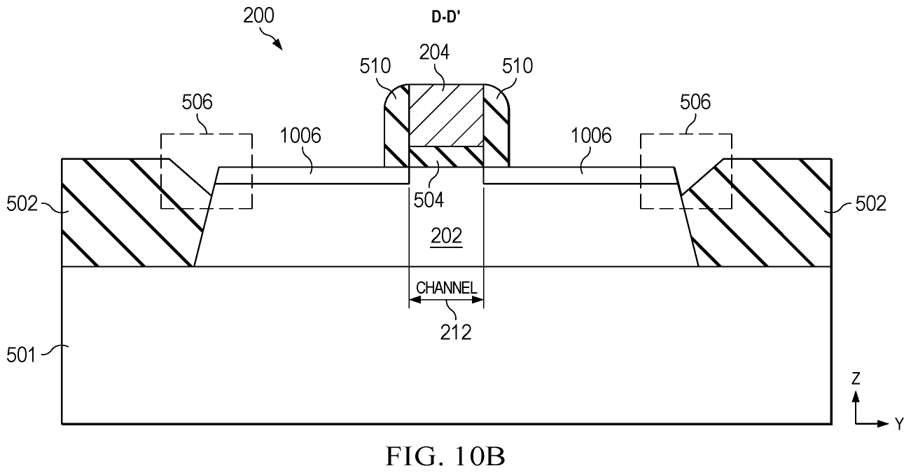

FIGS. 9A and 9B respectively illustrate a top-down plan view of FET 200 and cross-sectional side elevation view of FET 200 taken along D-D′ of FIG. 9A during a second step of the fabrication process, in accordance with embodiments of the present disclosure. As shown in FIGS. 9A and 9B, during such second step a gate structure may be formed over active region 202, such gate structure including gate 204 and gate oxide 504. A step similar to this second step may also be used to fabricate FET 700. FIGS. 10A and 10B respectively illustrate a top-down plan view of FET 200 and cross-sectional side elevation view of FET 200 taken along D-D′ of FIG. 10A during a third step of the fabrication process, in accordance with embodiments of the present disclosure. As shown in FIGS. 10A and 10B, during such third step, lightly-doped drain layer 1006 may be formed on either side of gate 204 and gate spacers 510 formed upon lightly-doped drain layer 1006 on either side of gate 204. A step similar to this third step may also be used to fabricate FET 700.

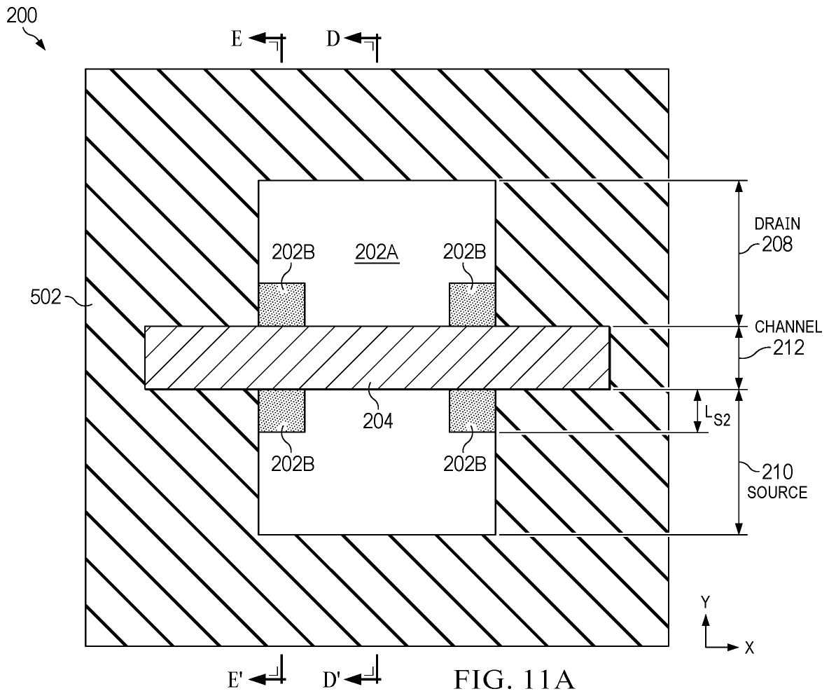

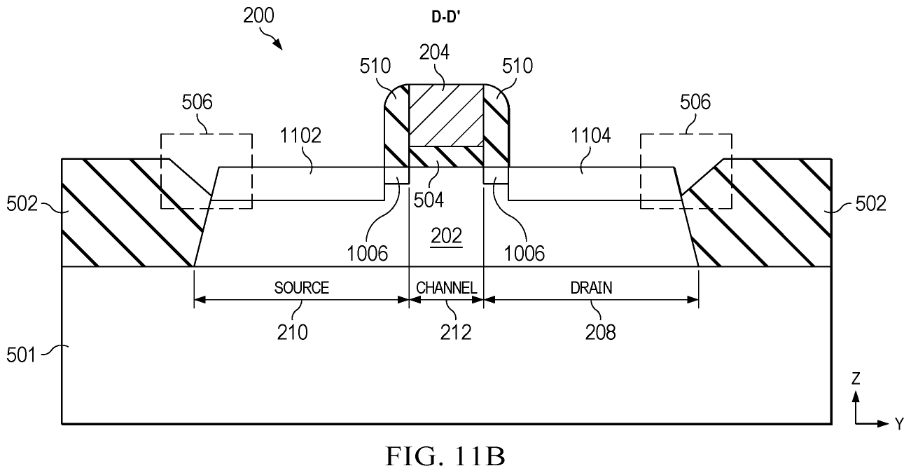

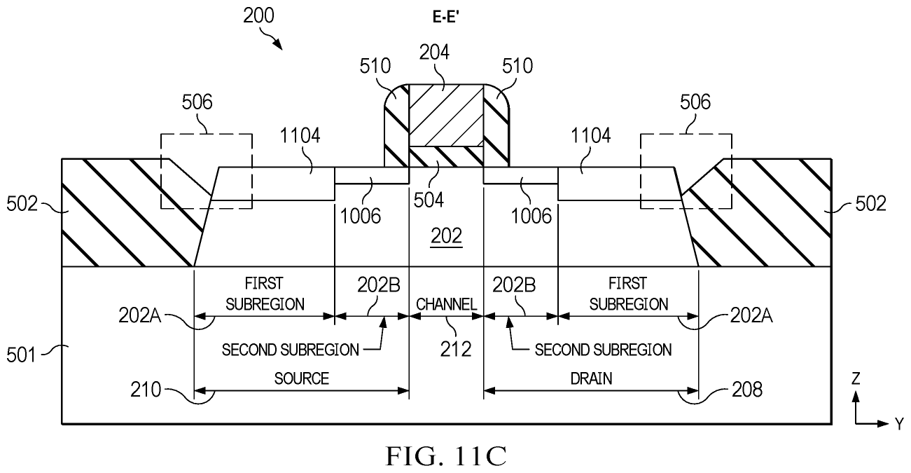

FIGS. 11A, 11B, and 11C respectively illustrate a top-down plan view of the FET 200, a first cross-sectional side elevation view of the FET 200 taken along D-D′ of FIG. 11A during a fourth step of a fabrication process and a second cross-sectional side elevation view of the FET 200 taken along E-E′ of FIG. 11A during the fourth step of the fabrication process, in accordance with embodiments of the present disclosure. As shown in FIGS. 11A, 11B, and 11C, during such fourth step portions of source region 210 may be doped with source doping 1102 and portions of drain region 208 may be doped with drain doping 1104, thus defining subregions 202A and 202B in each of drain region 208 and source region 210. In some embodiments, a step similar to this fourth step may also be used to fabricate FET 700.

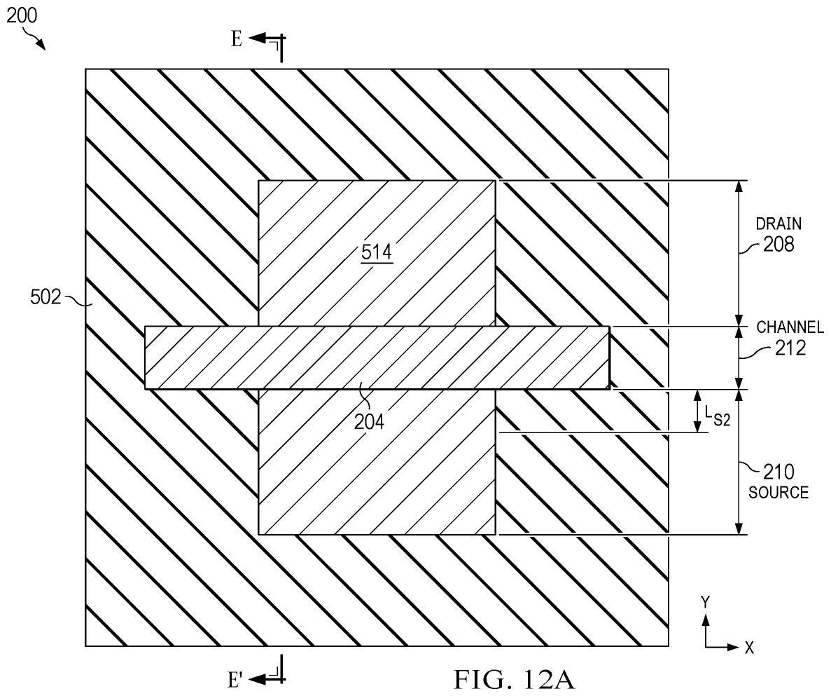

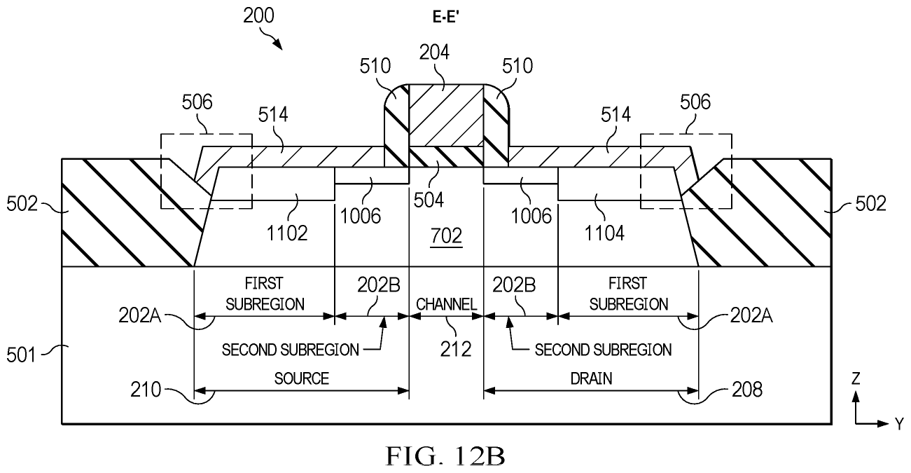

FIGS. 12A and 12B respectively illustrate a top-down plan view of FET 200 and cross-sectional side elevation view of FET 200 taken along E-E′ of FIG. 12A during a fifth step of the fabrication process, in accordance with embodiments of the present disclosure. As shown in FIGS. 12A and 12B, during such fifth step, silicide 514 may be formed over source region 210 and drain region 208.

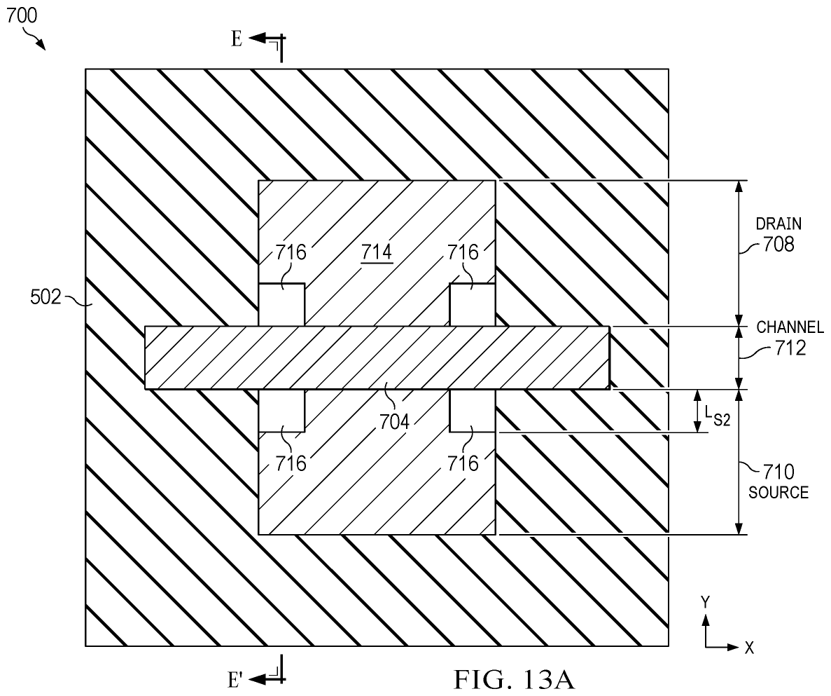

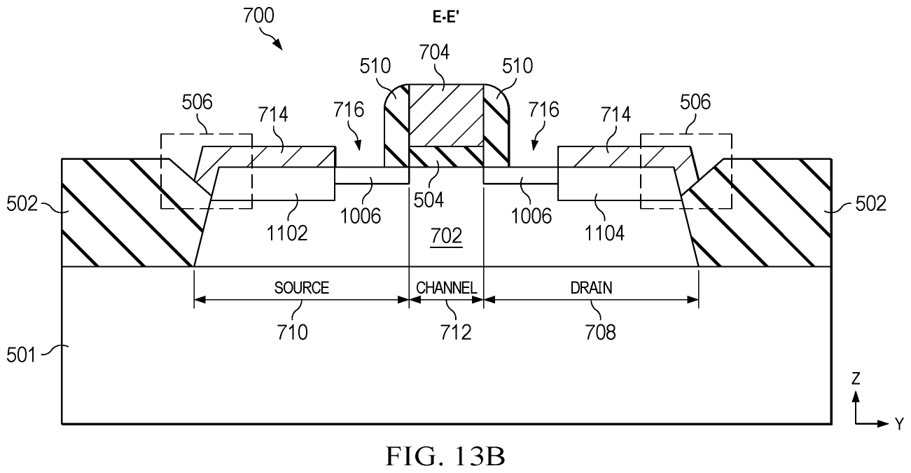

FIGS. 13A and 13B respectively illustrate a top-down plan view of FET 700 and cross-sectional side elevation view of FET 700 taken along E-E′ of FIG. 12A during an alternate fifth step of the fabrication process, in accordance with embodiments of the present disclosure. As shown in FIGS. 13A and 13B, during such alternate fifth step silicide layer 714 may be formed over only a portion of source region 710 and drain region 708, with voids 716 in silicide layer 714 present proximate to gate 704 at the edges of active region 702, thus splitting active region 702 into a drain region 708, a source region 710, and a channel region 712. In some embodiments, although not shown, silicide layer 714 may be formed selectively on first subregion 202A with voids in silicide layer 714 presenting proximate to gate 704 and over second subregions 202B.

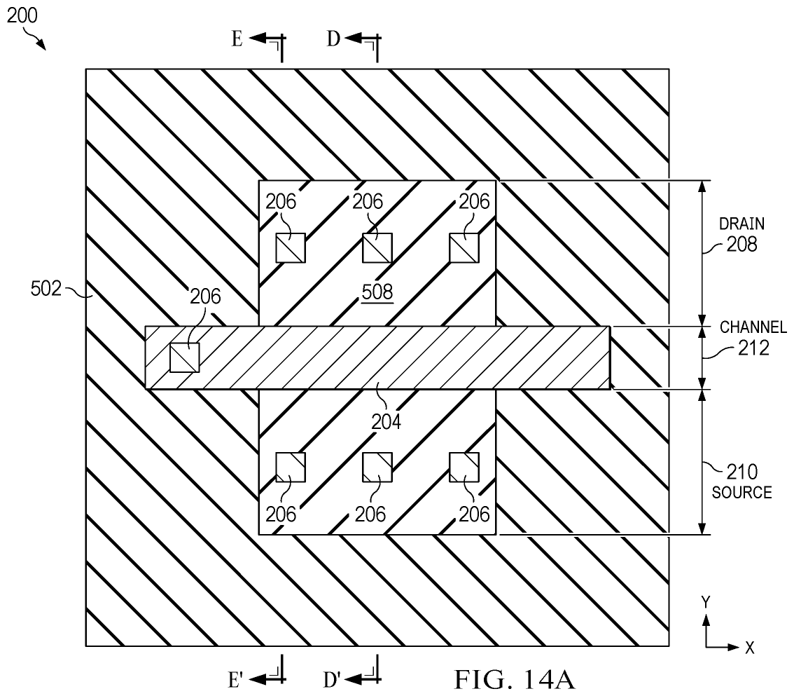

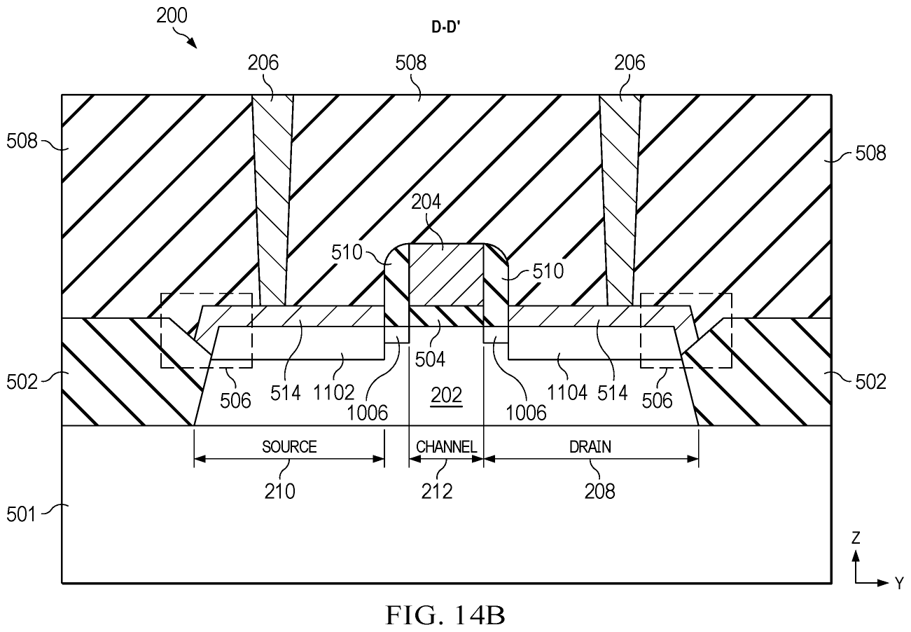

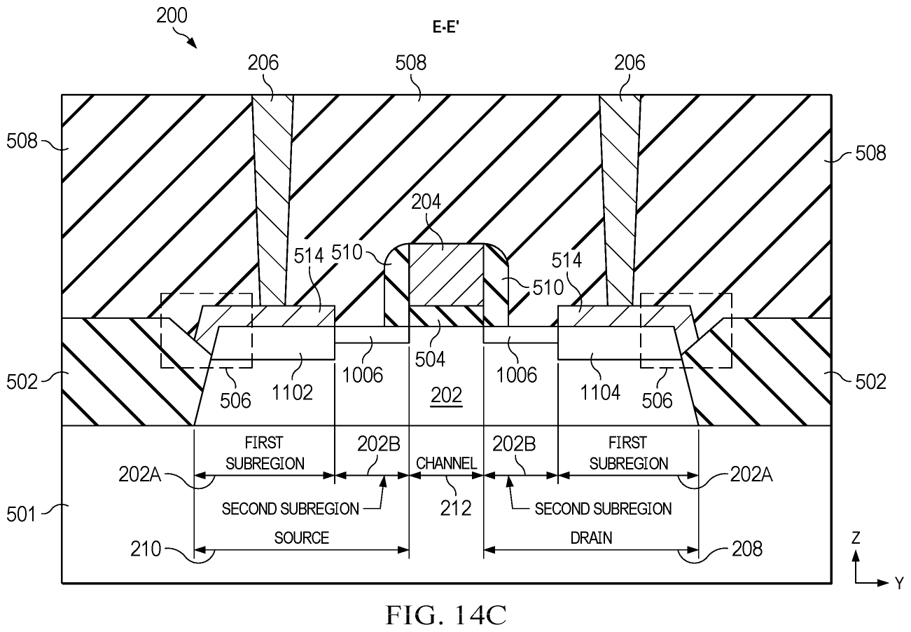

FIGS. 14A, 14B, and 14C respectively illustrate a top-down plan view of the FET 200, a first cross-sectional side elevation view of the FET 200 taken along D-D′ of FIG. 14A during a sixth step of a fabrication process and a second cross-sectional side elevation view of the FET 200 taken along E-E′ of FIG. 14A during the sixth step of the fabrication process, in accordance with embodiments of the present disclosure. Notably, FIGS. 14A, 14B, and 14C depict such sixth step being applied after the alternative fifth step of FIGS. 13A and 13B, such that subregions 202B are present under voids in silicide layer 514. As shown in FIGS. 14A, 14B, and 14C, during such sixth step vias 206 may be formed to provide electrical coupling to gate 204, source region 210, and drain region 208. Dielectric 508 may be formed over components of FET 200 such that vias 206 are formed within dielectric 508. A step similar to this sixth step may also be used to fabricate FET 700.

Although FIGS. 8A-14C show specific steps in fabrication of FET 200 and FET 700, steps other than those depicted may be used in fabrication of FET 200 and FET 700.

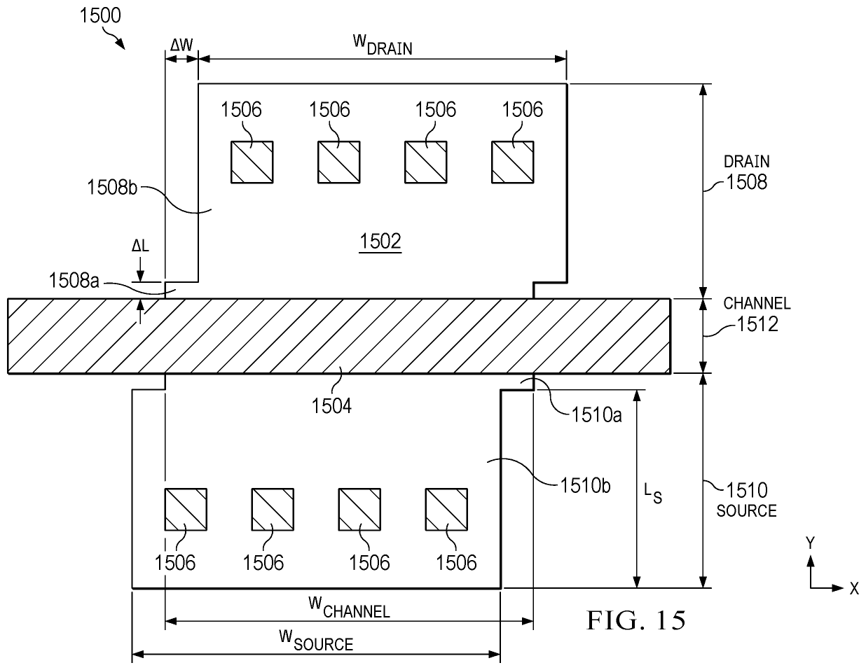

FIG. 15 illustrates a top-down plan view of an example FET 1500 with an active area 1502 which is staggered on either side of a gate 1504 of FET 1500, in accordance with embodiments of the present disclosure. As shown in FIG. 15, FET 1500 may include active region 1502 formed in a semiconductor substrate (e.g., silicon wafer), with gate 1504 formed over active region 1502, and one or more vias 1506 formed upon active region 1502 and gate 1504, thus splitting active region 1502 into a drain region 1508, a source region 1510, and a channel region 1512.

FET 1500 may be formed using an STI process, thus resulting in parasitic transistors being present in divots resulting from the STI process. However, as compared to FET 100, due to active region 1502 being staggered on either side of gate 1504, as described in greater detail below, parasitic transistors of FET 1500 may have conductive paths with greater resistance as compared to that of parasitic transistors 116 in FET 100.

As shown in FIG. 15, channel region 1512 may have a width W_{CHANNEL}, drain region 1508 may have a first subregion 1508a with a width W_{DRAIN} and a second subregion 1508b with width W_{CHANNEL}, and source region 1510 may have a first subregion 1510a with a width W_{SOURCE} and a second subregion 1510b with width W_{CHANNEL}. In some embodiments, W_{DRAIN}=W_{SOURCE}=W_{CHANNEL}. Also, second subregion 1510b may have length L_{S}. In some embodiments, second subregion 1508b may have a length similar to that of length L_{S} of second subregion 1510b.

Further, as shown in FIG. 15, in the x-direction, first subregion 1508a may be offset from second subregion 1508b by an offset ΔW, and likewise, first subregion 1510a may be offset from second subregion 1510b by offset ΔW. Further, as shown in FIG. 15, in the y-direction, first subregion 1508a may be offset from second subregion 1508b by an offset ΔL, and likewise, first subregion 1510a may be offset from second subregion 1510b by offset ΔL. In some embodiments, only one of drain region 1508 and source region 1510 may be staggered (e.g., in some embodiments, ΔW=ΔL=0 for drain region 1508 and ΔW≠0 and ΔL≠0 for source region 1510, or vice versa).

To provide sufficient extra resistance in the paths of the parasitic transistors of FET 1500 to overcome the subthreshold bump effect, it may be required that ΔW≥ΔL. In some embodiments, based on a sheet resistance of a silicide layer (not shown) of FET 1500, offset ΔW may be several times that of offset

$$Δ L ( e . g . , \frac{Δ W}{Δ L} \geq 3. ) .$$

Further, in these and other embodiments it may be required that offset ΔW is greater than a surface depletion width (e.g., ΔW≥0.05 μm) to provide sufficient extra resistance in the path of the parasitic transistors of FET 1500. Moreover, in these and other embodiments, ΔL≈0. In addition, in these and other embodiments, it may be desirable that the extra resistance present in the paths of the parasitic transistors of FET 1500 be comparable to the on-resistance of the core transistor of

$$FET 1500 ( e . g . , \frac{Δ W}{Δ L} \geq \frac{{L}_{S}}{{W}_{SOURCE}} ) .$$

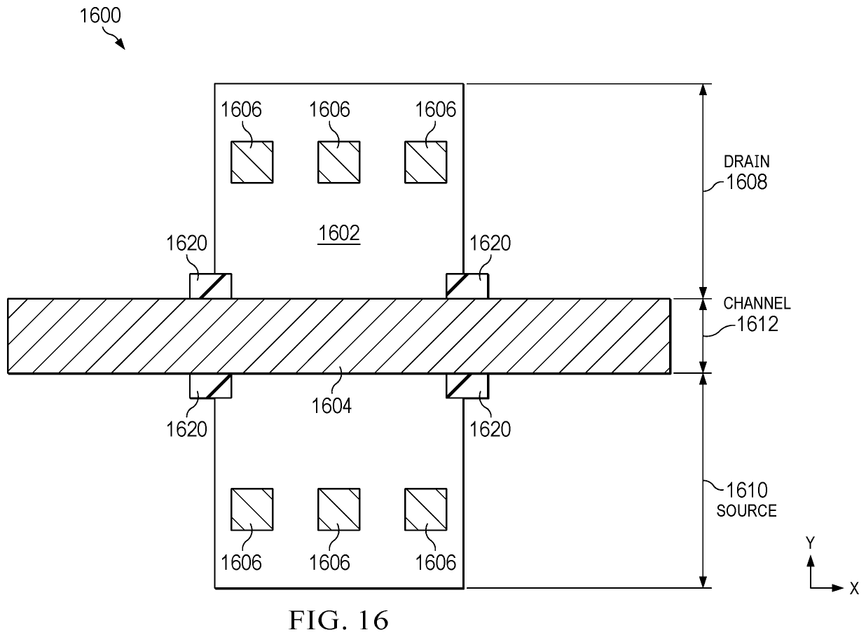

FIG. 16 illustrates a top-down plan view of an example FET 1600 with pad layer 1620 formed under a gate 1604 of FET 1600 proximate to parasitic transistors of FET 1600, in accordance with embodiments of the present disclosure. As shown in FIG. 16, FET 1600 may include an active region 1602 formed in a semiconductor substrate (e.g., silicon wafer), with a gate 1604 formed over active region 1602, and one or more vias 1606 formed upon active region 1602 and gate 1604, thus splitting active region 1602 into a drain region 1608, a source region 1610, and a channel region 1612. Further, pad layer 1620 may be formed under gate 1604 proximate to edges of active region 1602.

In some cases, pad layer 1620 may be formed only at one side of gate 1604 in the y-direction. For example, pad layer 1620 may be formed only over source region 1610 but not over drain region 1608. Pad layer 1620 may be made of a dielectric layer. For example, pad layer 1620 may include a layer of silicon oxide, a layer of silicon nitride, a layer of silicon oxynitride, a high-k dielectric layer, such as a hafnium oxide layer, or a combination thereof.

FET 1600 may be formed using an STI process, thus resulting in parasitic transistors being present in divots resulting from the STI process. However, as compared to FET 100, due to the presence of pad layer 1620, parasitic transistors of FET 1600 may have a greater threshold voltage as compared to that of parasitic transistors 116 in FET 100, thus potentially minimizing the subthreshold bump effect in FET 1600.

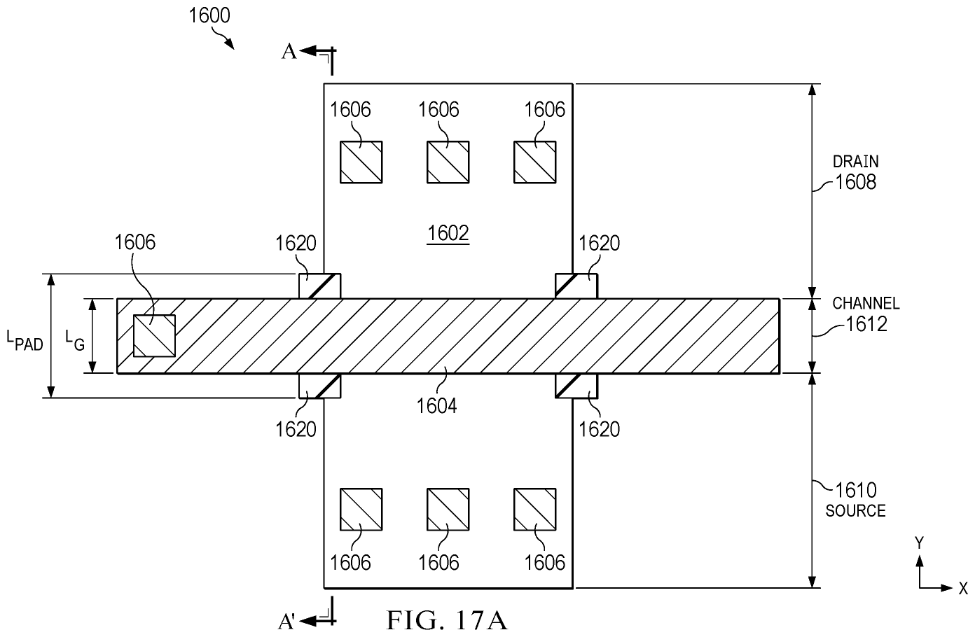

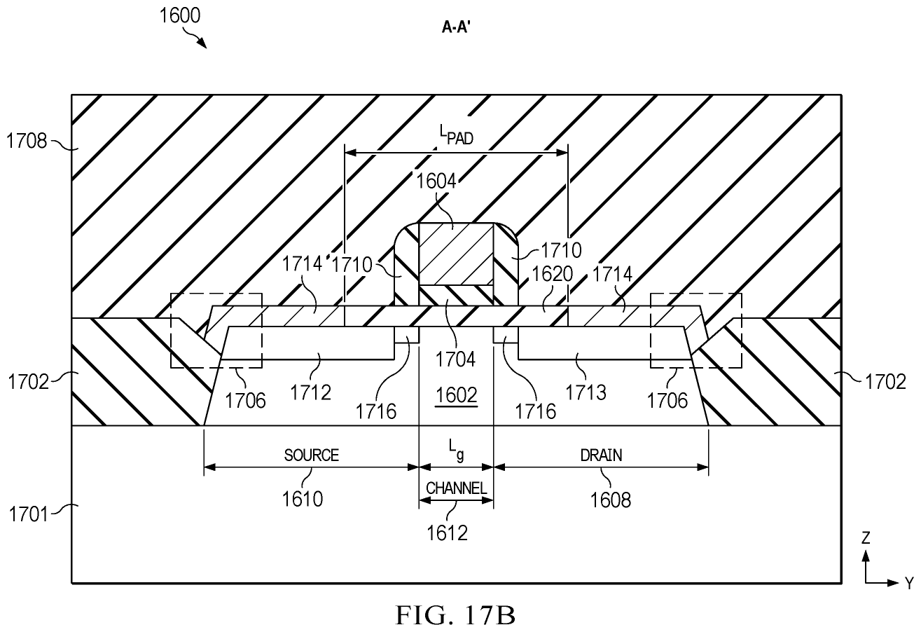

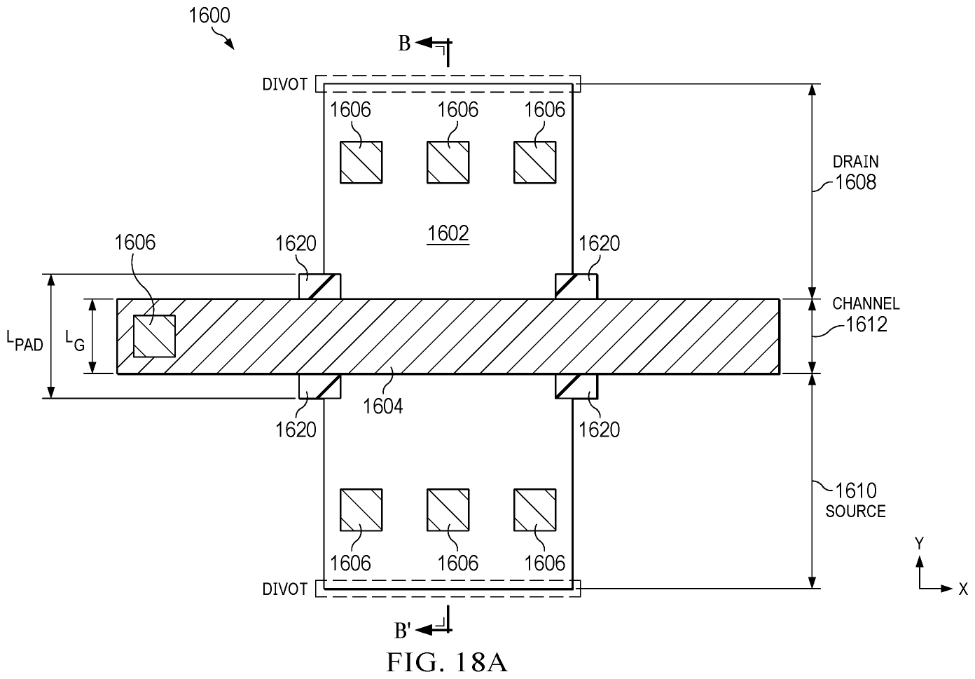

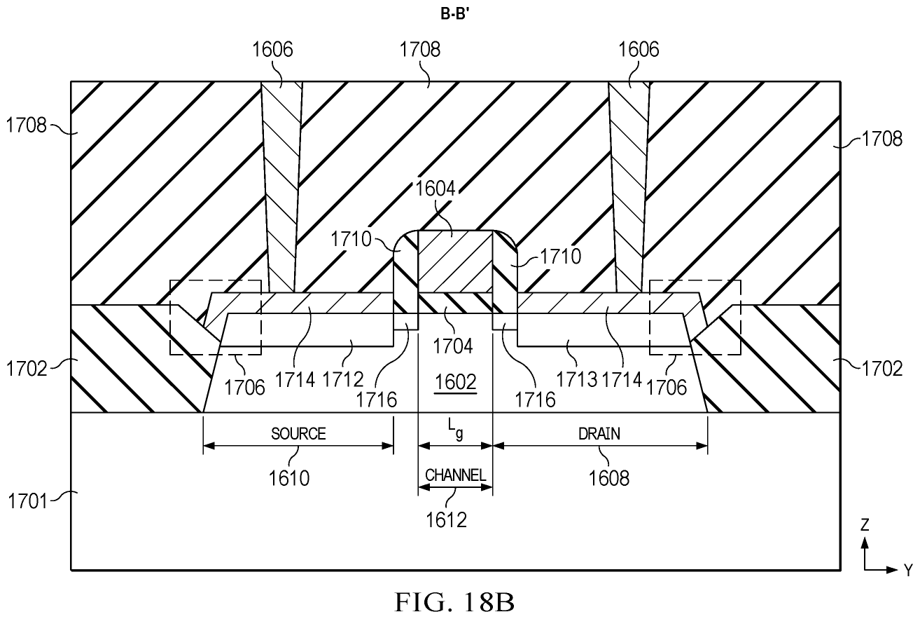

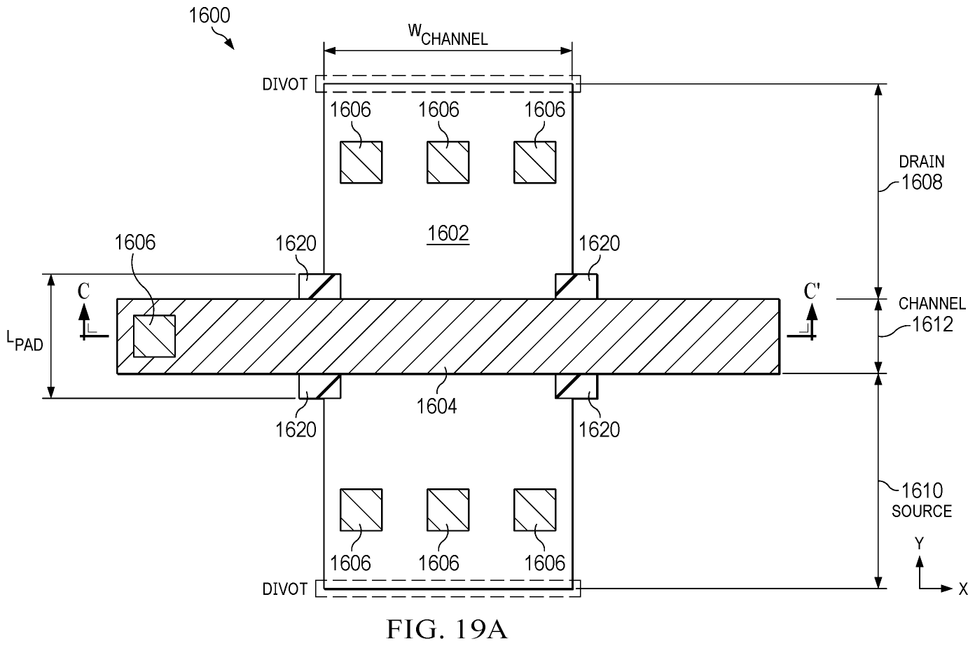

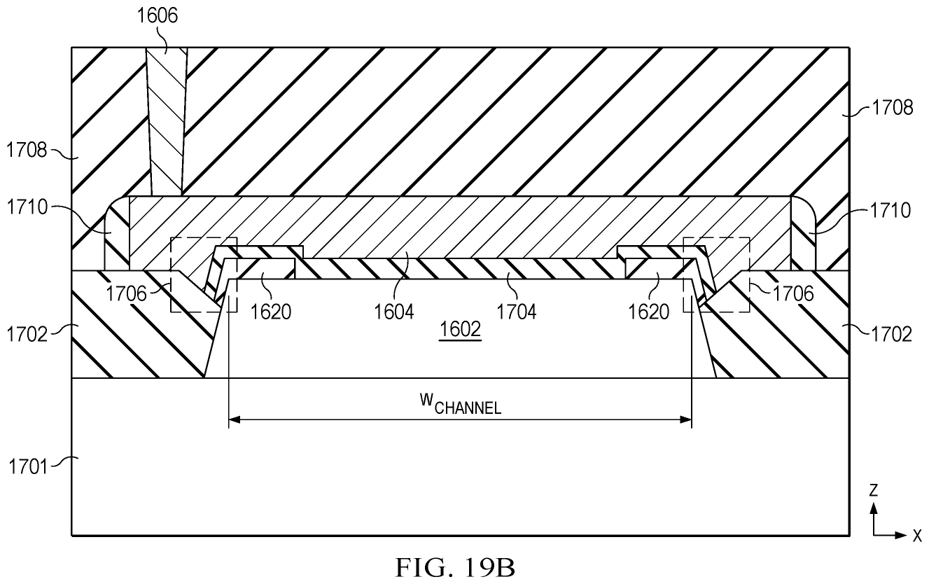

FIG. 17A illustrates a top-down plan view of FET 1600 and FIG. 17B illustrates a cross-sectional side elevation view of the FET 1600 taken along A-A′ of FIG. 17A, in accordance with embodiments of the present disclosure. FIG. 18A illustrates a top-down plan view of FET 1600 and FIG. 18B illustrates a cross-sectional side elevation view of the FET 1600 taken along B-B′ of FIG. 18A, in accordance with embodiments of the present disclosure. FIG. 19A illustrates a top-down plan view of FET 1600 and FIG. 19B illustrates a cross-sectional side elevation view of the FET 1600 taken along C-C′ of FIG. 19A, in accordance with embodiments of the present disclosure.

Notably, FIGS. 17B, 18B, and 19B depict STI made of silicon oxide (SiO) 1702 formed on substrate 1701 adjacent to channel region 1612 of active region 1602, which may leave divots 1706 along edges of active region 1602 in channel region 1612. FIGS. 17B and 18B additionally show source doping 1712 in source region 1610 and drain doping 1713 in drain region 1608, and light drain doping 1716 being added to active region 1602 proximate to gate 1604. FIGS. 17B, 18B, and 19B also depict a gate oxide 1704 present between the electrode of gate 1604 and channel region 1612, to provide dielectric insulation between gate 1604 and channel region 1612. FIGS. 17B, 18B, and 19B further depict gate spacers 1710 formed adjacent to gate 1604, a silicide layer 1714 formed over drain region 1608 and source region 1610, a dielectric layer 1708 formed over the features of FET 1600, and vias 1606 formed within dielectric layer 1708 to provide electrical connections to drain region 1608, source region 1610, and gate 1604. Moreover, FIGS. 17B and 19B show pad layer 1620 formed under gate 1604 proximate to edges of active region 1602.

As seen in FIGS. 17B and 19B, pad layer 1620 may be located under gate oxide 1704 and gate spacers 1710. Thus, in some cases, pad layer 1620 may provide separation preventing light drain doping 1716, source doping 1712, and drain doping 1713 from contacting gate spacers 1710 and gate oxide 1704. Further, pad layer 1620 may prevent silicide layer 1714 from contacting gate spacers 1710 and gate oxide 1704 along A-A′ (e.g., an edge portion of active region 1602), while silicide layer 1704 may be in contact with gate spacers 1710 along B-B′ (e.g., a central portion of active region 1602).

The presence of pad layer 1620 may boost the threshold voltages of the parasitic transistors of FET 1600, thus reducing or eliminating the subthreshold bump. In some instances, a thickness of pad layer 1620 may need to be a sufficient thickness in the z-direction (e.g., ≥10 nm), in order to sufficiently boost the threshold voltage of the parasitic transistors of FET 1600.

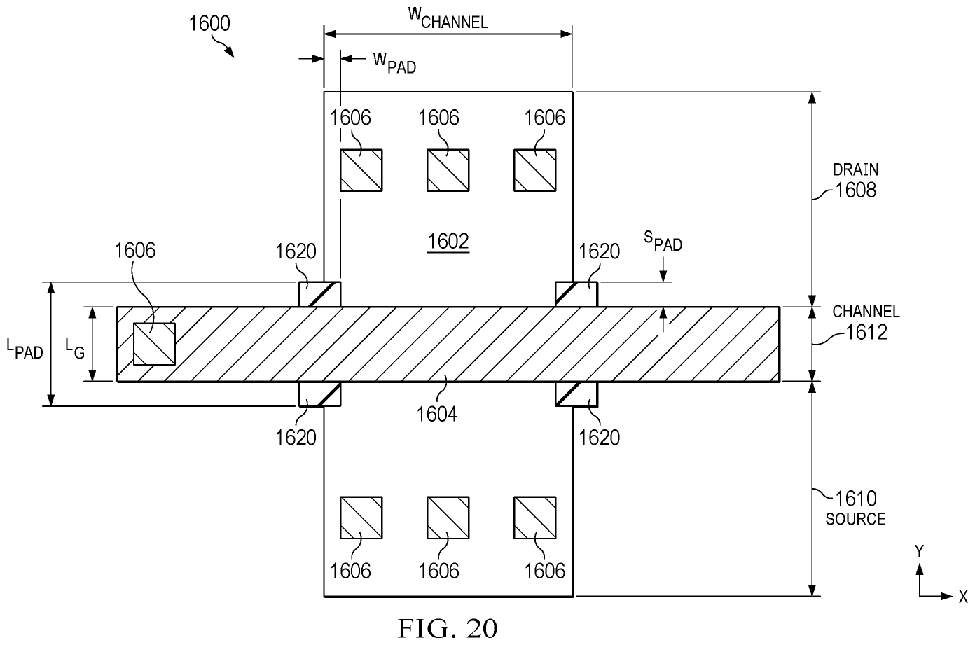

FIG. 20 illustrates a top-down plan view of FET 1600, with certain physical dimensions annotated, in accordance with embodiments of the present disclosure. As shown in FIG. 20, drain region 1608, source region 1610, and channel region 1612 may all have equal width W_{CHANNEL}. Pad layer 1620 may have an overlapping width W_{PAD} along the x-direction within active region 1602, and may have a length L_{PAD} along the y-direction. Further, a separation S_{PAD} may exist in the y-direction between an edge of gate 1604 and an edge of pad layer 1620. Also, gate 1604 may have a length L_{G} along the y-direction. Some of the physical dimensions depicted in FIG. 20 are also shown in FIGS. 17A-19B.

In some embodiments, overlapping width W_{PAD} may need to exceed a minimum distance (e.g., W_{PAD}≥0.05 μm) to ensure the parasitic transistor of FET 1600 has a sufficient boosted threshold voltage. Further, pad layer 1620 may not extend entirely through the entirety of active region 1602 in the X-direction. Otherwise, the threshold voltage of the core transistor may also be boosted. For example, in some cases, it may be desirable to maintain the ratio of overlapping width W_{PAD} to width W_{CHANNEL} below 0.05 to ensure the core transistor is able to supply sufficient drain current.

In some embodiments, it may be required that L_{PAD}>L_{G} to ensure complete boosting of the threshold voltage of a parasitic transistor. In addition, in some cases, separation S_{PAD} may need to be a minimum distance (e.g., S_{PAD}≥0.05 μm) to separate silicide layer 1714 from gate 1604 at an edge portion of active region 1602 (e.g., along A-A′ of FIG. 17A).

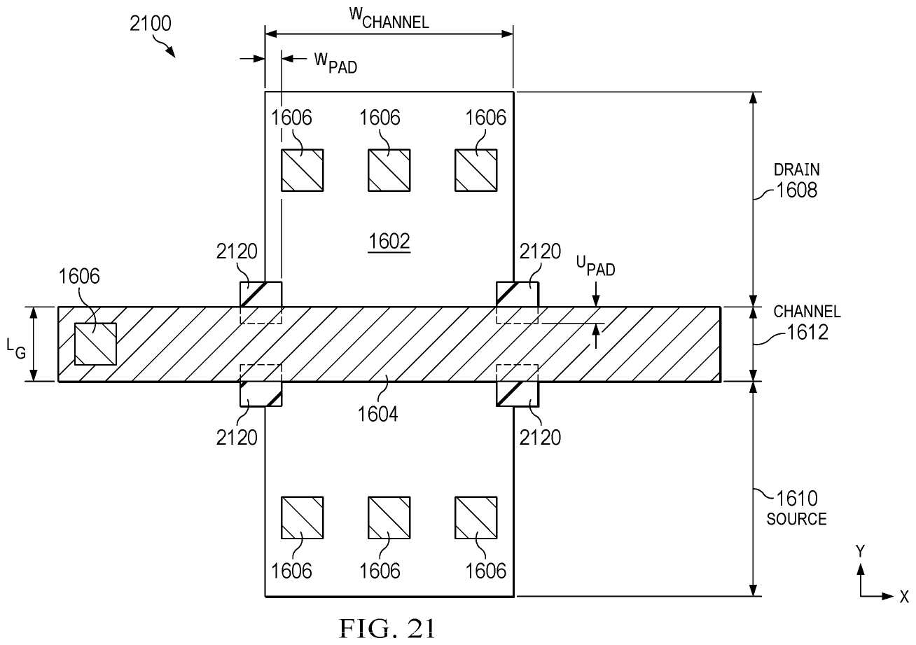

FIG. 21 illustrates a top-down plan view of an example FET 2100 with pad oxides 2120 partially formed under a gate 1604 of FET 2100 proximate to parasitic transistors, in accordance with embodiments of the present disclosure. FET 2100 may be similar in many respects to FET 1600, except that pad oxides 2120 may not fully extend across length L_{G} of gate 1604, but instead may underlap gate 1604 in the y-direction by an underlap length U_{PAD}. In some cases, the ratio of underlap length U_{PAD} to length L_{G} may be below a maximum amount

$$( e . g . , \frac{{U}_{PAD}}{{L}_{G}} \leq 0.25 )$$

in order to ensure satisfaction of time-dependent dielectric breakdown lifetime and/or hot carriers injection lifetime requirements of the core transistor of FET 2100.

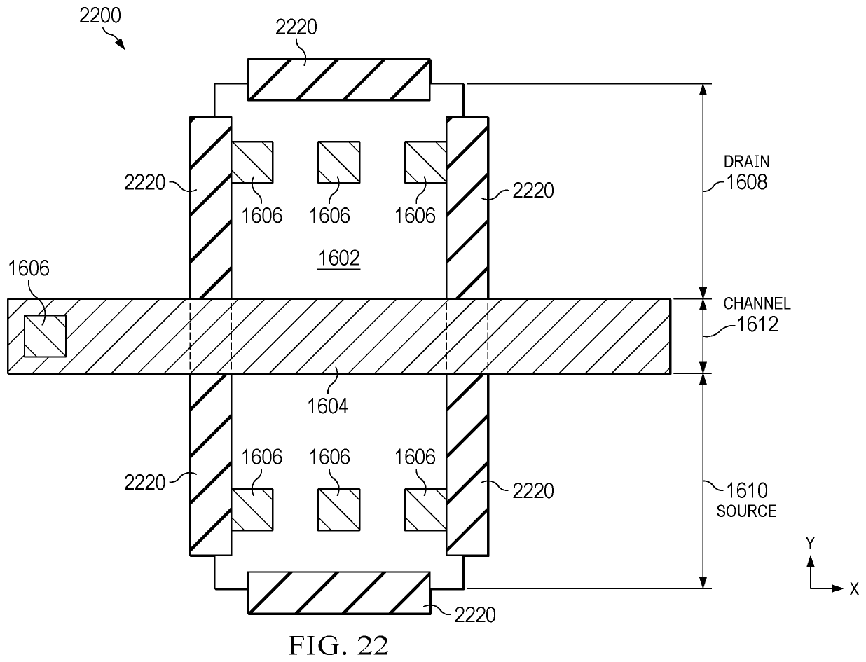

FIG. 22 illustrates a top-down plan view of an example FET 2200 with a pad layer 2220 partially formed at the edges of active region 1602 of FET 2200, in accordance with embodiments of the present disclosure. FET 2200 may be similar in many respects to FET 1600, except that pad layer 2220 may be present along a majority of active region 1602 of FET 2200.

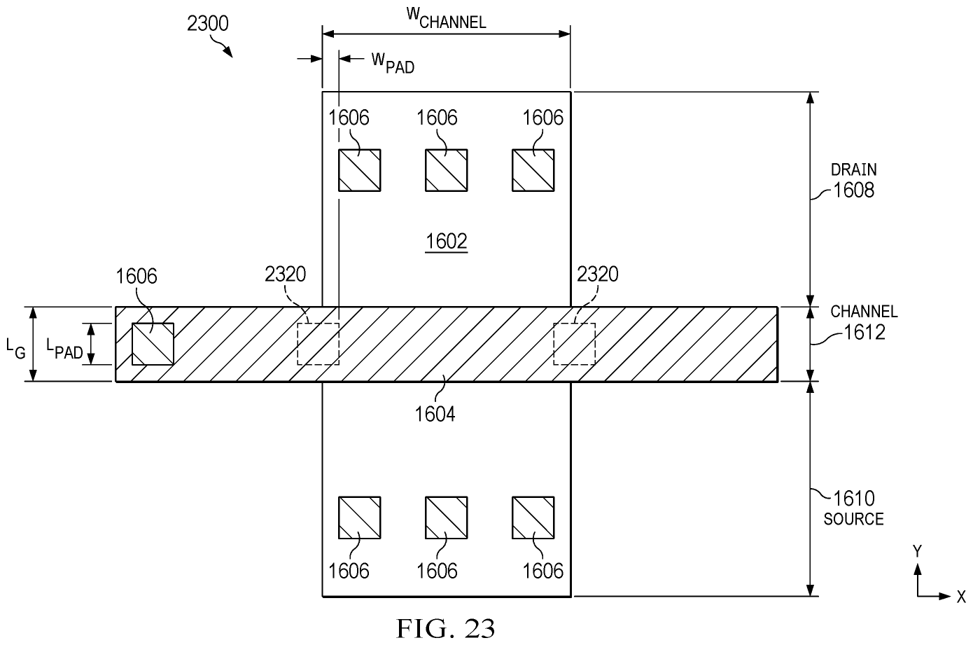

FIG. 23 illustrates a top-down plan view of an example FET 2300 with pad oxides 2320 formed entirely under gate 1604 of FET 2300 proximate to parasitic transistors, in accordance with embodiments of the present disclosure. FET 2300 may be similar in many respects to FET 1600, except that pad oxides 2320 of FET 2300 may have a length L_{PAD} in the y-direction smaller than length L_{G} of gate 1604 in the y-direction, such that pad oxides 2320 are completely overlapped by gate 1604. In some case, the ratio of length L_{PAD} to length L_{G} may be below a maximum amount

$$( e . g . , \frac{{L}_{PAD}}{{L}_{G}} \leq 0.5 )$$

in order to ensure satisfaction of time-dependent dielectric breakdown lifetime and/or hot carriers injection lifetime requirements of the core transistor of FET 2300.

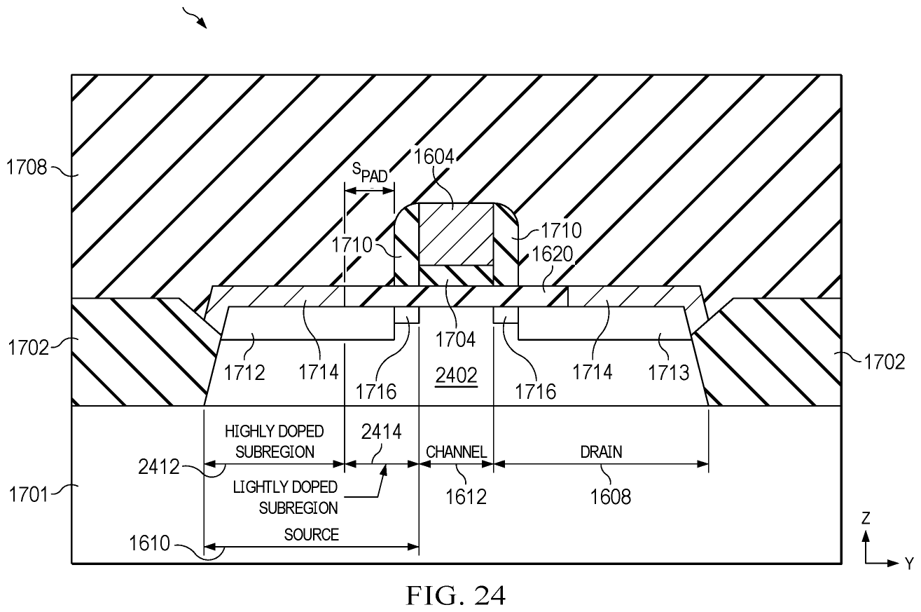

FIG. 24 illustrates cross-sectional side elevation of an example FET 2400 with a pad layer 1620 formed under gate 1604 of FET 2400 proximate to parasitic transistors, and with the source and/or drain of FET 2400 doped with different concentrations, in accordance with embodiments of the present disclosure. FET 2400 may be similar in many respects to FET 1600, except that like FETs 200 and 700, active region 2402 of FET 2400 may have drain doping 1712 and/or source doping 1713 with lighter-doped concentrations proximate to gate 1604, in order to form a highly-doped subregion 2412 and a lightly-doped subregion 2414 in source region 1610 and/or drain region 1608.

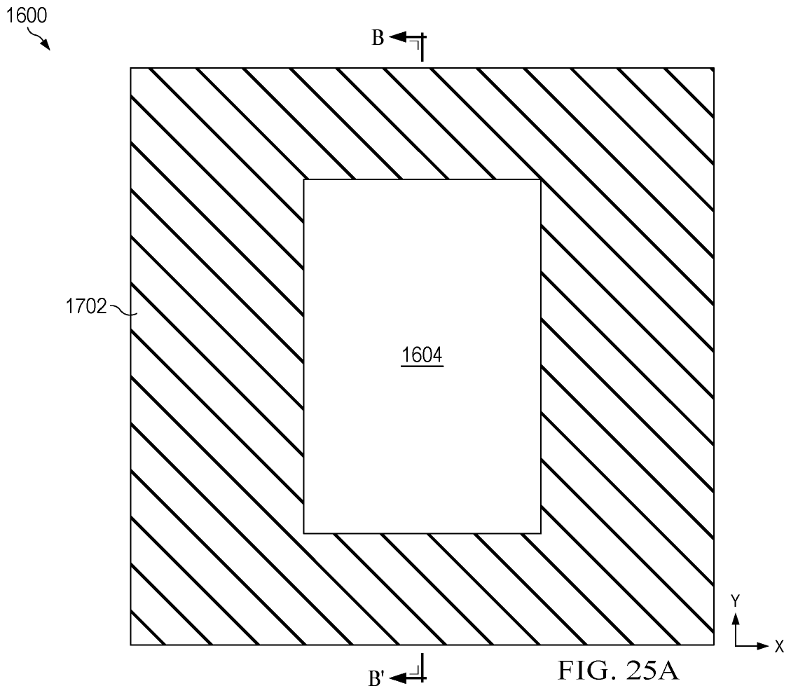

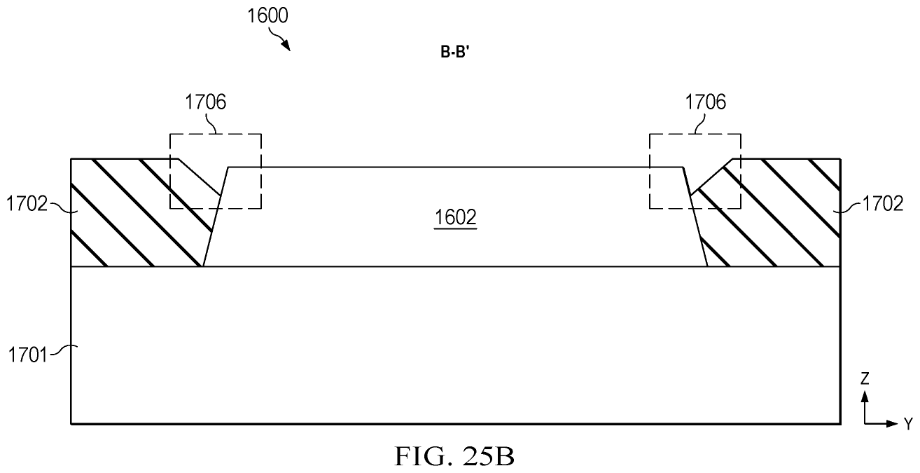

FIGS. 25A and 25B respectively illustrate a top-down plan view of FET 1600 and a cross-sectional side elevation view of FET 1600 taken along B-B′ of FIG. 25A during a first step of a fabrication process, in accordance with embodiments of the present disclosure. As shown in FIGS. 25A and 25B, during such first step, active region 1602 may be formed on substrate 1701, and STI may be performed to form a trench in SiO 1702, leaving divots 1706 between active region 1602 and SiO 1702. A step similar to this first step may also be used to fabricate FETs 2100, 2200, 2300, and/or 2400.

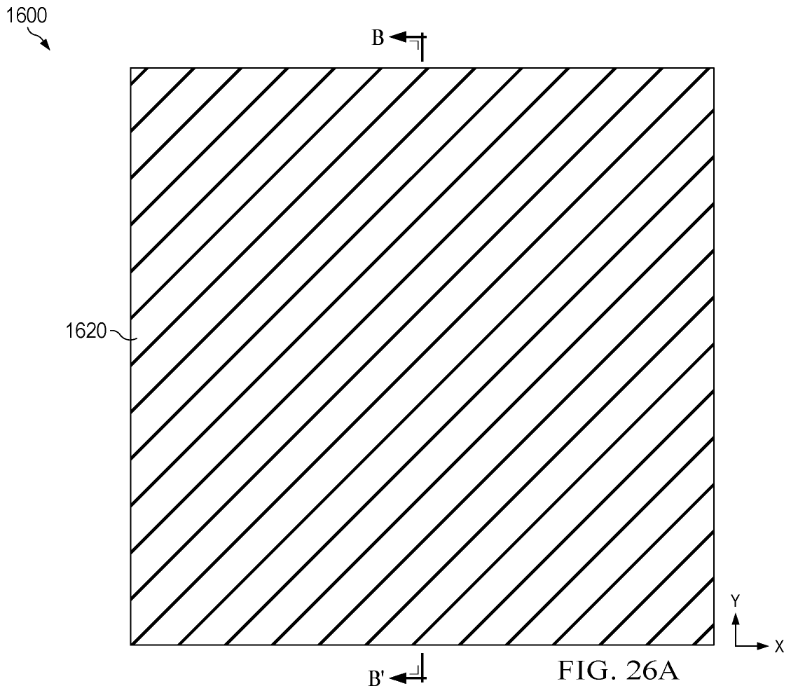

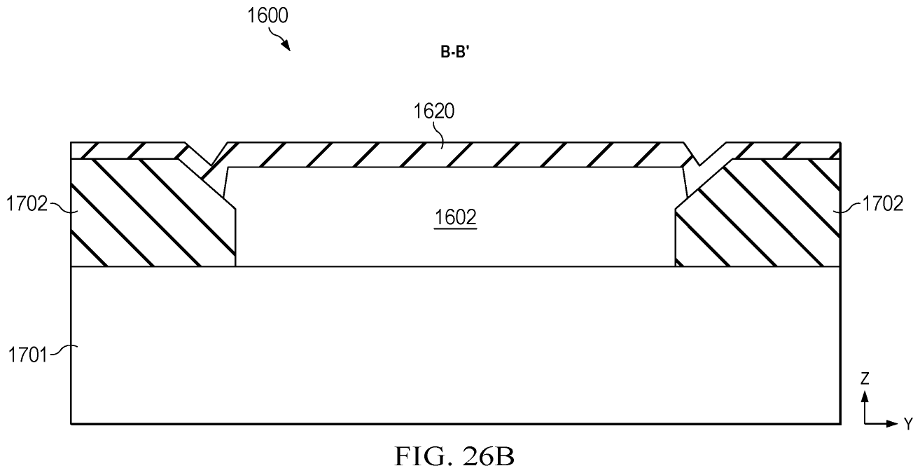

FIGS. 26A and 26B respectively illustrate a top-down plan view of FET 1600 and a cross-sectional side elevation view of FET 1600 taken along B-B′ of FIG. 26A during a second step of the fabrication process, in accordance with embodiments of the present disclosure. As shown in FIGS. 26A and 26B, during such second step, pad layer 1620 may be deposited over active region 1602 and SiO) 1702. A step similar to this second step may also be used to fabricate FETs 2100, 2200, 2300, and/or 2400.

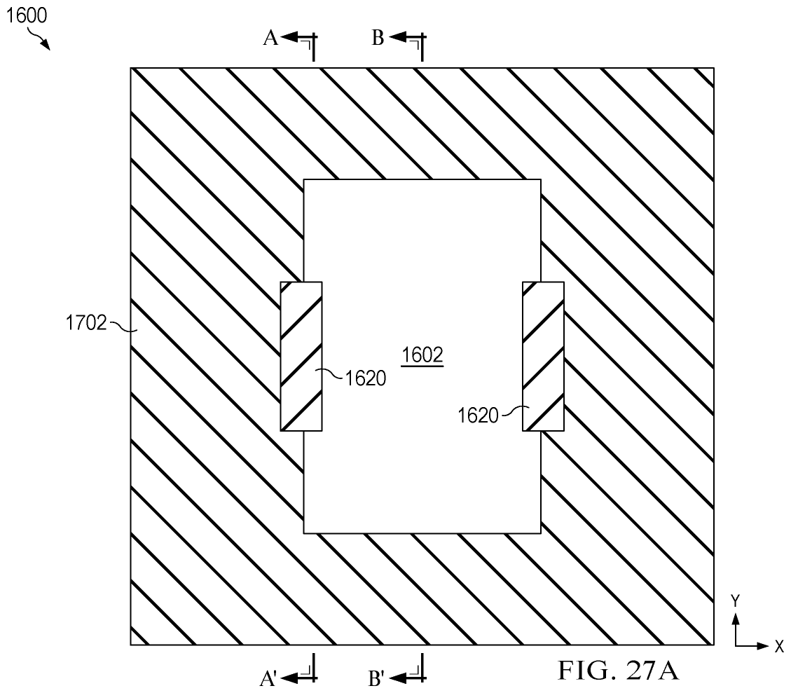

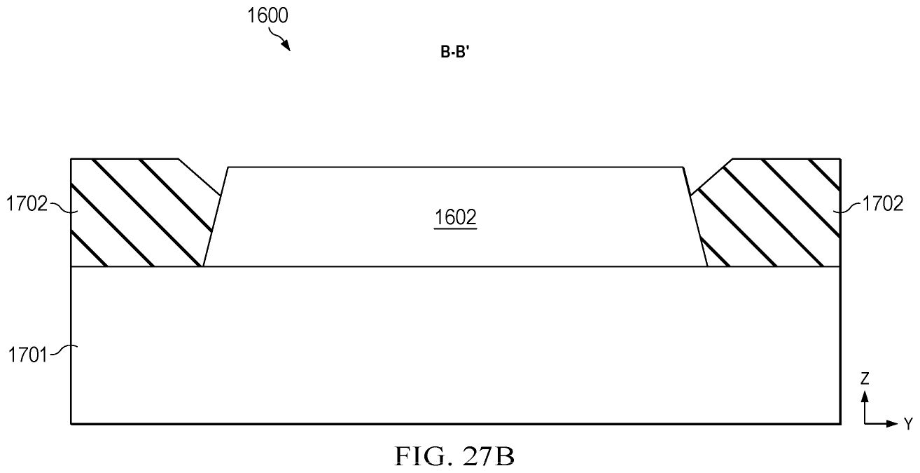

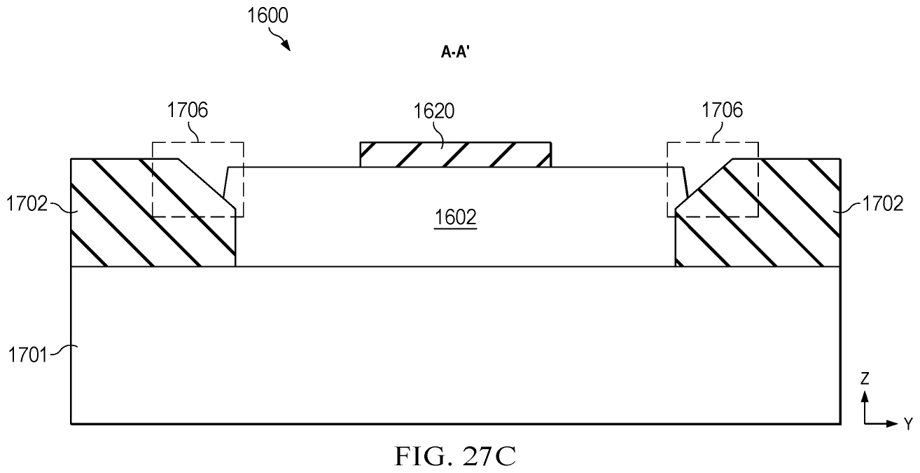

FIGS. 27A, 27B, and 27C respectively illustrate a top-down plan view of the FET 1600, a first cross-sectional side elevation view of FET 1600 taken along B-B′ of FIG. 27A during a third step of a fabrication process and a second cross-sectional side elevation view of FET 1600 taken along A-A′ of FIG. 27A during the third step of the fabrication process, in accordance with embodiments of the present disclosure. As shown in FIGS. 27A and 27B, during such third step, the pad layer 1620 may be patterned and etched to leave behind pad layer 1620 at desired locations. A step similar to this third step may also be used to fabricate FETs 2100, 2200, 2300, and/or 2400. After patterning of the pad layer 1620, the subsequent steps for fabricating FETs 1600, 2100, 2200, 2300, and/or 2400 may be similar to that used to fabricate FETs 200 and 700.

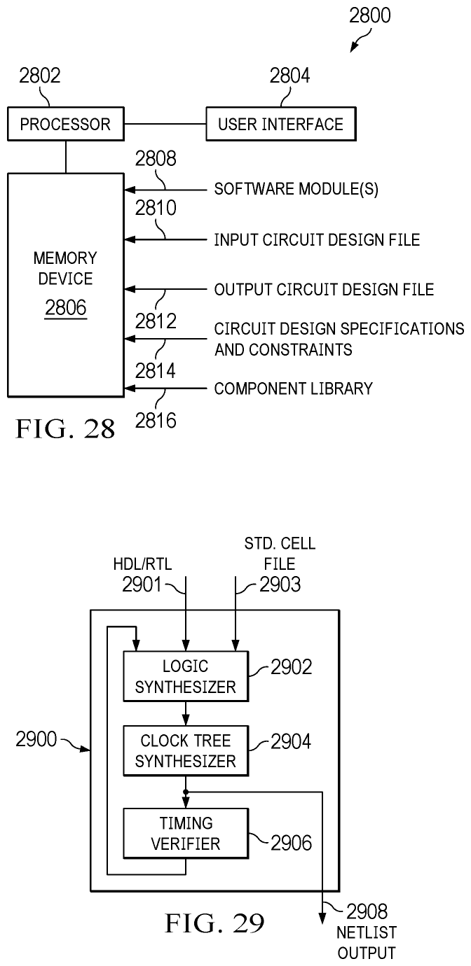

FIG. 28 illustrates a block diagram of an example circuit design system 2800, in accordance with embodiments of the present disclosure. Circuit design system 2800 may be capable of receiving and synthesizing, analyzing, and/or optimizing an initial circuit design that includes one or more of FETs 200, 700, 1600, 2100, 2200, 2300, and/or 2400. Circuit design system 2800 may comprise any computing device, such as a computer that has a processor 2802, a user interface 2804, and a memory device 2806.

Processor 2802 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 2802 may interpret and/or execute program instructions and/or process data stored in memory device 2806 and/or another component of circuit design system 2800.

Memory device 2806 may be communicatively coupled to processor 2802 and may include any system, device, or apparatus configured to retain program instructions and/or data for a period of time (e.g., computer-readable media). Memory device 2806 may include random access memory (RAM), read-only memory (ROM), electrically erasable programmable read-only memory (EEPROM), flash memory, magnetic storage, opto-magnetic storage, or any suitable selection and/or array of volatile or non-volatile memory that retains data after power to circuit design system 2800 is turned off. Memory device 2806 may store different types of instructions and/or data, including, but not limited to software module(s) 2808 including executable instructions that may be executed by processor 2802 (e.g., circuit design synthesis, analysis and/or optimization tools) to control processor 2802 in performing its various operations, an input circuit design file 2810, an output circuit design file 2812, circuit design specifications and constraints 2814, a component library 2816, and/or other data, information, or instructions. One or more of input circuit design file 2810, circuit design specifications and constraints 2814, and component library 2816 may include data and information for defining FETs 200, 700, 1600, 2100, 2200, 2300, and/or 2400.

User interface 2804 may comprise any instrumentality or aggregation of instrumentalities by which a user may interact with circuit design system 2800. For example, user interface 2804 may permit a user to input data and/or instructions into circuit design system 2800, and/or otherwise manipulate circuit design system 2800 and its associated components (e.g., via keyboard, mouse, trackpad, or other pointing device). User interface 2804 may also permit circuit design system 2800 to communicate data to a user, e.g., by way of a display device.

FIG. 29 illustrates a block diagram of an example synthesis software tool 2900, in accordance with embodiments of the present disclosure. Synthesis software tool 2900 may be stored as computer-readable instructions in memory device 2806 and readable and executable by the processor 2802 of circuit design system 2800. Synthesis software tool 2900 may comprise a logic synthesizer module 2902, a clock tree synthesizer module 2904, and a timing verifier 2906. Logic synthesizer module 2902 may receive a high-level description language (HDL) or register transfer level (RTL) circuit description 2901 and a standard cell technology file 2903. Functional logic may be generated from standard cell technology file 2903 by logic synthesizer module 2902, including the various FETs 200, 700, 1600, 2100, 2200, 2300, and/or 2400 that are in the data paths of circuit description 2901. Standard cell technology file 2903 may include data and information for characterizing FETs 200, 700, 1600, 2100, 2200, 2300, and/or 2400 as one or more standard cells. Clock tree synthesizer module 2904 may generate clock tree paths in the integrated circuit from a clock source to the clock inputs of the various elements including the various FETs 200, 700, 1600, 2100, 2200, 2300, and/or 2400 in the data paths. The timing verifier module 2906 may receive a netlist including data paths and clock tree paths of the integrated circuit design to verify that timing specifications are satisfied with the given logical design of the integrated circuit. Timing verifier module 2906 may verify that the timing specifications of the logical design are in fact met to output a netlist 2908. Netlist 2908 may be sent to a foundry for manufacturing of the integrated circuit described by netlist 2908.

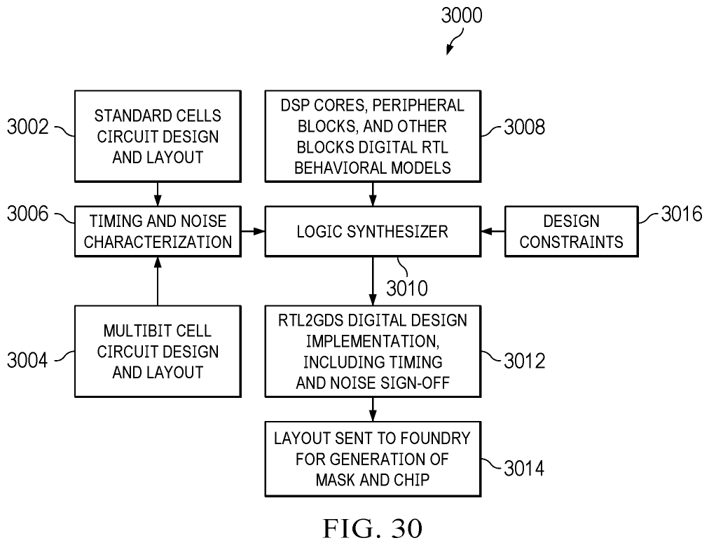

FIG. 30 illustrates a flow chart of an example method 3000 for synthesizing an integrated circuit design with FETs 200, 700, 1600, 2100, 2200, 2300, and/or 2400, in accordance with the present disclosure. Method 3000 may be embodied in instructions that are stored in memory device 2806 of circuit design system 2800 and read and executed by processor 2802. For example, method 3000 may be implemented by synthesis software tool 2900. In accordance with method 3000, at block 3002, a standard cell circuit design and layout for an integrated circuit design may be provided to a timing and noise characterization block 3006, and at block 3004, multi-bit cell circuit design and layout for the integrated circuit design that incorporate FETs 200, 700, 1600, 2100, 2200, 2300, and/or 2400 in accordance with the present disclosure may also be provided to timing and noise characterization block 3006. The timing and noise characterization block 3006 may provide timing and noise characterizations of the integrated circuit design to logic synthesizer module 2902 at logic synthesizer process block 3010. Characterizations of the laid-out standard cells and the laid-out multi-bit cells (including FETs 200, 700, 1600, 2100, 2200, 2300, and/or 2400) may also be provided to logic synthesizer module 2902 at logic synthesizer process block 3010. The digital RTL behavioral models of block 3008 may be among the RTL circuit description 2901 provided to logical synthesizer processor block 3010. RTL behavioral models of block 3008 may include but are not limited to digital signal processing (DSP) cores, peripheral blocks, and other blocks that may be digitally designed. Furthermore, the design constraints of block 3016, that may include, without limitation, various parameters for characterizing FETs 200, 700, 1600, 2100, 2200, 2300, and/or 2400, may also be provided to logic synthesizer process block 3010. Within logic synthesizer process block 3010, logic synthesizer 2902 synthesizes the data and information relating to the laid-out standard cells, the laid-out multi-bit cells, the timing and noise characterizations, the various digital RTL behavioral models, and the design constraints to provide a physical design layout that results in an RTL to Graphic Data System (“GDS”) digital design implementation at block 3012. GDS is a format that may be used to control integrated circuit photomask plotting. The RTL-to-GDS digital design implementation includes at least the timing information and noise sign-off information. The GDS file containing the physical design layout information may be sent to a foundry for generation of a mask and the semiconductor chip at block 3014.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A semiconductor structure comprising:
a substrate having a surface;
an isolation structure formed on the surface;
an active region formed on the surface adjacent to the isolation structure;
a gate extended over the isolation structure and the active region; and
a source region formed within the active region, the source region comprising:
a first subregion formed adjacent to a first portion of the gate and the isolation structure, the first subregion having a first doping; and
a second subregion formed adjacent to a second portion of the gate, wherein the second subregion has a second doping different from the first doping.

2. The semiconductor structure of claim 1, wherein a first concentration of the first doping is less than a second concentration of the second doping.

3. The semiconductor structure of claim 1, wherein a first dopant for doping the first subregion with the first doping is different from a second dopant for doping the second subregion with the second doping.

4. The semiconductor structure of claim 1, further comprising a silicide layer formed over the second subregion, in contact with the second subregion, and separated from the first subregion.

5. The semiconductor structure of claim 1, further comprising a pad layer formed between the second subregion and the gate.

6. A semiconductor structure comprising:
a substrate having a surface;
an isolation structure formed on the surface;
an active region formed on the surface adjacent to the isolation structure;
a gate extended over the isolation structure and the active region;
a source region formed within the active region, the source region comprising:
a first subregion formed adjacent to the gate and the isolation structure; and
a second subregion formed adjacent to the gate, wherein the first subregion is surrounded by the isolation structure and the second subregion; and
a silicide layer formed over the second subregion, in contact with the second subregion, and separated from the first subregion.

7. The semiconductor structure of claim 6, further comprising a dielectric layer formed over the silicide layer, and wherein the dielectric layer is in contact with the first subregion.

8. The semiconductor structure of claim 6, further comprising a pad layer formed between the gate and the active region.

9. The semiconductor structure of claim 6, wherein a doping of the first subregion is less than another doping of the second subregion.

10. An integrated circuit comprising:
a substrate having a surface;
an isolation structure formed on the surface; and
a transistor over the substrate comprising:
an active region formed on the surface adjacent to the isolation structure;
a gate extended over the isolation structure and the active region; and
a source region formed within the active region, the source region comprising:
a first subregion formed adjacent to a first portion of the gate and the isolation structure, the first subregion having a first doping; and
a second subregion formed adjacent to a second portion of the gate, wherein the second subregion has a second doping different from the first doping.

11. The integrated circuit of claim 10, wherein a first concentration of the first doping is less than a second concentration of the second doping.

12. The integrated circuit of claim 10, wherein a first dopant for doping the first subregion with the first doping is different from a second dopant for doping the second subregion with the second doping.

13. The integrated circuit of claim 10, further comprising a silicide layer formed over the second subregion, in contact with the second subregion, and separated from the first subregion.

14. The integrated circuit of claim 10, further comprising a pad layer formed between the second subregion and the gate.

15. An integrated circuit comprising:
a substrate having a surface;
an isolation structure formed on the surface; and
a transistor over the substrate comprising:
an active region formed on the surface adjacent to the isolation structure;
a gate extended over the isolation structure and the active region;
a source region formed within the active region, the source region comprising:
a first subregion formed adjacent to the gate and the isolation structure; and
a second subregion formed adjacent to the gate, wherein the first subregion is surrounded by the isolation structure and the second subregion; and
a silicide layer formed over the second subregion, in contact with the second subregion, and separated from the first subregion.

16. The integrated circuit of claim 15, further comprising a dielectric layer formed over the silicide layer, and wherein the dielectric layer is in contact with the first subregion.

17. The integrated circuit of claim 15, further comprising a pad layer formed between the gate and the active region.

18. The integrated circuit of claim 15, wherein a doping of the first subregion is less than another doping of the second subregion.

19. A method comprising:
forming an isolation structure on a surface of a substrate;
forming an active region on the surface adjacent to the isolation structure;
extending a gate over the isolation structure and the active region; and
forming a source region formed within the active region, the source region comprising:
a first subregion adjacent to a first portion of the gate and the isolation structure, the first subregion having a first doping; and
a second subregion adjacent to a second portion of the gate, wherein the second subregion has a second doping different from the first doping.

20. A method comprising:
forming an isolation structure on a surface of a substrate;
forming an active region on the surface adjacent to the isolation structure;
extending a gate over the isolation structure and the active region;
forming a source region within the active region, the source region comprising:
a first subregion adjacent to the gate and the isolation structure; and
a second subregion adjacent to the gate, wherein the first subregion is surrounded by the isolation structure and the second subregion; and
forming a silicide layer over the second subregion, in contact with the second subregion, and separated from the first subregion.
